(19) United States
(12) Patent Application Publication
(10) Pub. No.: US 2010/0314723 A1
(43) Pub. Date: Dec. 16, 2010

(54) MANUFACTURING OF OPTICAL STRUCTURES BY ELECTROTHERMAL FOCUSSING

(76) Inventors: Christian Schmidt, Le Bouveret (CH); Leander Dittmann, Lausanne (CH)

Correspondence Address: Pearl Cohen Zedek Latzer, LLP, 1500 Broadway, 12th Floor, New York, NY, 10036, US

(21) Appl. No.: 12/747,660

(22) PCT Filed: Dec. 12, 2008
(86) PCT No.: PCT/EP08/05950

§ 371 Date: Jul. 23, 2010

(30) Foreign Application Priority Data
Jul. 20, 2007 (DE) 10 2007 034 415.7

(51) Int. Cl. H01L 29/02; H01L 21/326

(52) U.S. Cl. 257/629; 438/466; 257/E21.327; 257/E29.002

(57) ABSTRACT

This invention relates to methods and devices for the production of optical microstructures or domains in dielectric substrates based on electrothermal focussing. More specifically, the invention relates to a method of introducing a change of dielectric and/or optical properties in a region of an electrically insulating or electrically semiconducting substrate, and to substrates produced by such method.

### FIELD OF THE INVENTION

This invention relates to methods and devices for the production of optical microstructures or domains in dielectric substrates based on electrothermal focussing. More specifically, the invention relates to a method of introducing a change of dielectric and/or optical properties in a region of an electrically insulating or electrically semiconducting substrate, and to substrates produced by such method.

### BACKGROUND OF THE INVENTION

The presence of domains within a substrate having optical properties which are different to the bulk of the substrate is desired in many applications. In such a substrate, there exists one or several regions which have for example altered absorption or refraction capabilities and hence it may therefore be used in photonic, optoelectronic or other optical applications. Previous methods of manufacturing such substrates having regions of altered optical and/or dielectric properties involved e.g. the production of composite substrates wherein different parts were joined together, layers of different materials were sequentially deposited or bulk material was partially removed/altered by processes such as etching. It has proved particularly difficult to produce substrates wherein the regions having altered optical/dielectric properties have dimensions on a micrometer scale or even smaller, which is particularly important for processing of light from infrared red range to UV and even x-ray. It has also been difficult to produce substrates having regions of altered optical/dielectric properties, which regions have aspect ratios of ≧10. It has also been difficult to produce substrates having regions of altered optical/dielectric properties arranged in a 3-dimensional manner such as 3D photonic structures/crystals. It has also been difficult to produce substrates comprising regions which have altered optical/dielectric properties, wherein the method of production is easily performed and does not involve the manufacture of composite structures involving gluing or other error-prone connection techniques.

Accordingly, it was an object of the present invention to provide for a method of producing substrates comprising regions which have altered optical/dielectric properties, which method is easy and simple to perform and allows the production of such regions on a micrometer scale and below. It was also an object of the present invention to provide for a method of producing a substrate comprising regions of altered dielectric/optical properties which method does not necessarily alter the physical dimensions or the weight or the volume of the substrate.

### SUMMARY OF THE INVENTION

All these objects are solved by a method of introducing a change of dielectric and/or optical properties in a first region of an electrically insulating or electrically semiconducting substrate, such that, after performance of said method, said first region has altered dielectric and/or optical properties in comparison to other regions surrounding said first region, said method comprising the steps:
a) providing an electrically insulating or electrically semiconducting substrate, which has optical or dielectric properties that may be irreversibly altered upon a temporary increase in substrate temperature, and which, optionally, has an electrically conducting or insulating or semi-conducting layer of material attached,
b) providing electrical energy to said substrate using a voltage supply, said electrical energy being sufficient to significantly heat and/or melt parts or all of said first region, said electrical energy not being sufficient to cause a significant ejection of material from said first region,
c) optionally, applying additional energy, preferably heat, to said substrate, preferably to a part of said substrate comprising said first region, and thereby initiate a current flow and, subsequently, a dissipation of said electrical energy within said substrate to define the location of said first region in which said change of dielectric and/or optical properties is to be introduced on said substrate,
d) dissipating said electrical energy, wherein said dissipating manifests itself in a current flow within said substrate and wherein the rate of dissipating said electrical energy is controlled by a current and power modulating element, said current and power modulating element being either part of an electrical connection between said voltage supply and said substrate, or being part of said voltage supply, said dissipating introducing said altered dielectric and/or optical properties in said first region of said substrate.

In one embodiment said electrical energy is not sufficient to cause the formation of a through hole or through channel in said first region.

In one embodiment said first region, after performance of said method, has altered optical properties in comparison to other regions surrounding said first region, wherein, preferably said optical properties are selected from transmission, reflection, refraction, dispersion, filtering, polarization, dielectric constant, magnetic permeability, optical isotropy, optical anisotropy of light interacting with said first region, and any combination of the foregoing properties.

In one embodiment step b) is performed by applying a voltage across said first region of said substrate by means of said voltage supply, said voltage supply being electrically connected to said substrate, wherein, preferably, step d) occurs in that said voltage supply supplies an electrical current to said substrate and, preferably, to said first region, and said electrical current and/or the time over which said current is supplied is controlled by said current and power modulating element or, if said current and power modulating element is part of said voltage supply, by said voltage supply, said voltage supply having a variable impedance, said variable impedance being adjusted under the control of an automated control and/or feedback circuit.

Preferably, said current and power modulating element is an electronic feedback mechanism which, preferably, comprises a current and/or voltage analysis circuit such as a trigger circuit alone or as part of a user programmed device, such as a computer, said current and/or voltage analysis circuit preferably being capable of controlling the trans-substrate voltage and electrical current flow of step d) according to user-predefined procedures, such as steadily reducing or turning off such voltage supply and/or energy storage element output once a user specified trans-substrate current threshold is exceeded.

Preferably, said electronic feedback mechanism is an ohmic resistor which is connected in series between said substrate and said voltage supply.

Preferably, said ohmic resistor is chosen such that it has a resistance in the range of from 0.01-100 kΩ if said substrate has a thickness ≧1 μm, and a resistance >100 kΩ if said substrate has a thickness <1 μm.

In one embodiment said ohmic resistor is chosen in terms of its resistance such that said resistor leads to a reduction of the trans-substrate voltage of at least a factor of 2, preferably a factor of 5 during step d), compared with otherwise identical conditions but in the absence of a resistor.

In one embodiment step b) is performed by applying a voltage across said first region of said substrate by means of said voltage supply and charging an energy storage element with said electrical energy, said energy storage element being electrically connected in parallel to said substrate and said voltage supply, and wherein said current and power modulating element is part of the electrical connection between said energy storage element and said substrate, wherein, preferably, the amount of said electrical energy stored across said substrate and charged to said energy storage element is user-defined in relation to substrate parameters, such as substrate area, substrate thickness, heat capacity of substrate, coefficient of thermal conduction of substrate, and process parameters, such as maximum temperature occurring during step d).

Preferably, said amount of electrical energy is in the range of from 1-5000 mJ/mm substrate thickness, preferably 10-500 mJ/mm substrate thickness.

In one embodiment the method according to the present invention comprises the step:
c) applying additional energy, preferably heat, to said substrate, preferably to a part of said substrate comprising said first region, and thereby initiate a current flow and, subsequently a dissipation of said electrical energy within said substrate, wherein, preferably, by the performance of step c), the position of said first region in which a change of dielectric and/or optical properties is introduced, is defined.

In one embodiment said first region, after performance of said method, has cross sectional dimensions in the range of from x to y, wherein x>1 nm and y<50 μm.

In one embodiment said first region extends from a first surface of said substrate to the inside of said substrate and, preferably, to a second surface of said substrate which second surface is opposite said first surface.

In one embodiment said first region has a shape determined by a path of energy dissipation of step d) and extends across said substrate.

In one embodiment said first region has a rod-like shape or cylindrical shape or paralleliped shape.

In one embodiment said first region has uniform optical properties along said path of energy dissipation as defined above.

In one embodiment said first region, after performance of the method according to the present invention, has non-uniform optical or dielectric properties in a direction perpendicular to said path of energy dissipation. Preferably, said non-uniform optical or dielectric properties occur in subregions which are concentrically arranged around said path of energy dissipation, with each of the subregions itself having constant optical or dielectric properties. For example these subregions may be concentrically and cylindrically arranged around said path of energy dissipation. In one embodiment said subregions thus establish a gradient of optical or dielectric properties in a direction perpendicular to said path of energy dissipation. For example the optical property may be refractive index; in this embodiment a gradient refractive index is established in radial direction around said path of energy dissipation. Such gradient refractive index may for example be used in a micro lense, and said first region may therefore act as a micro lense.

In one embodiment said first region extends perpendicular from said first surface to said second surface.

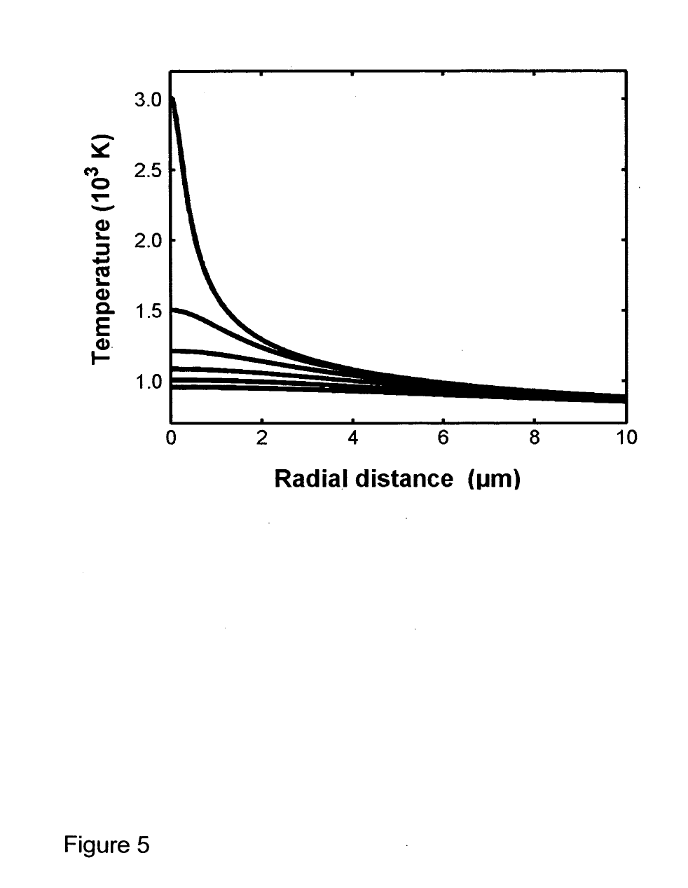

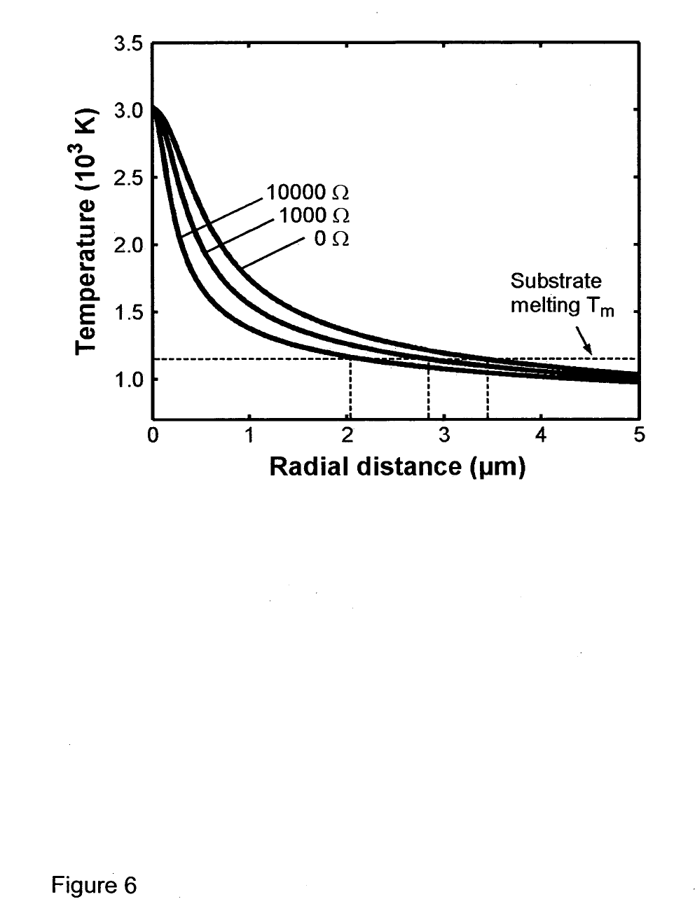

In one embodiment said optical properties are refraction of light interacting with or incident upon said first region and a corresponding refractive index of material within said first region, wherein, preferably, said first region has a light refraction and corresponding refractive index such that light coupled into said first region is totally reflected within said first region. Total reflection may, e.g., occur on the border of said first region to the bulk substrate material or of said first region to the material surface depending on the refractive indices. Total reflection may also happen in terms of a gradient refractive index profile in the first region (see T(r)-plot) (FIGS. 5 and 6).

In one embodiment said first region has an aspect ratio of ≧10, preferably ≧100.

In one embodiment said substrate provided in step a) has an electrically conducting or semi-conducting or insulating layer of material attached, e.g. a metal layer or a silicon layer, wherein, preferably, said method comprises the further step
e) fully or partially removing said electrically conducting or semi-conducting or insulating layer of material from said substrate.

In one embodiment performing steps a)-d) does not lead to a change of geometry or physical dimensions of said substrate, wherein, preferably, performing steps a)-d) does not lead to a change of volume or weight of said substrate.

In one embodiment said method including steps a)-d) is additionally performed in a second region and optionally further regions of said substrate, wherein said performance of said method is done concomitantly with the method performed in said first region, using multiple electrodes and using an optical pattern of light spots generated on a surface of said substrate, e.g. generated by a laser source, wherein each light spot determines the locations of said second region and further regions of said substrate in which said altered dielectric and/or optical properties are to be introduced, wherein, preferably, said first, second and further regions are alike in shape and dimensions.

Preferably, said first, second and further regions are located parallel to each other.

In another embodiment at least some of said first, second and further regions intersect with each other.

In one embodiment at least some of said first, second and further regions having altered dielectric and/or optical properties are generated from a first surface of said substrate and others of said first, second and further regions having altered dielectric and/or optical properties are generated from a second surface of said substrate, said second surface of said substrate being opposite said first surface, wherein, preferably, said second surface is inclined or parallel or perpendicular to said first surface.

Preferably, said energy storage element and, preferably also said voltage supply, is connected to said substrate by electrodes, which electrodes either touch said substrate or touch a medium, said medium being in contact with said substrate, wherein said medium is a liquid or gaseous or solid medium which is electrically conducting or can be made electrically conducting, e.g. by ionisation.

Preferably, said energy storage element and said voltage supply are connected to said substrate by the same electrodes.

In one embodiment said voltage supply is a high impedance voltage supply, wherein preferably said high impedance voltage supply has an impedance >10 kΩ more preferably >100 kΩ and, even more preferably >1 MΩ.

In another embodiment said energy storage element is a low impedance energy storage element, wherein preferably said low impedance is an impedance ≦10 kΩ.

In one embodiment, upon dissipation of said electrical energy, said voltage supply provides further electrical energy to be stored across the substrate by charging it to said energy storage element, wherein, preferably, steps b)-d) are repeated at least once, preferably several times, with a user-defined delay after the end of step d) and before performance of a next step b).

In one embodiment said dissipation of said electrical energy in step d) occurs by an electrical current being supplied from said energy storage element to said substrate and through said first region and thereby transforming said electrical energy into heat which heat will heat and/or melt substrate material in said first region, wherein, preferably, said electrical current is supplied to said substrate via said current and power modulating element, said current and power modulating element controlling and/or modulating step d), and thereby controlling the transformation of said electrical energy into heat.

Preferably, said electrical current being supplied to said substrate and subsequently flowing through said substrate in step d) has a temporary maximum of 1 uA-1 A, if maintenance of the physical dimensions or volume or weight of said substrate is required.

In one embodiment said dissipation in step d) occurs at a stored electrical energy resulting in a trans-substrate voltage across said substrate of at least 5V/micrometer substrate thickness.

In one embodiment said current and power modulating element is an electronic feedback mechanism which, preferably, comprises a current and/or voltage analysis circuit such as a trigger circuit alone or as part of a user programmed device, such as a computer, said current and/or voltage analysis circuit preferably being capable of controlling the trans-substrate voltage and electrical current flow of step d) according to user-predefined procedures, such as steadily reducing or turning off such voltage supply and/or energy storage element output once a user specified trans-substrate current threshold is exceeded.

In one embodiment said additional energy, preferably heat, originates either from an additional energy source, preferably a heat source, or from performing step b) on said substrate, wherein, preferably, said additional energy source is a heated electrode or a heating element placed near by said substrate or a laser or other focussed light source or a gas flame.

In one embodiment said current and/or voltage analysis circuit also is capable of controlling said additional energy or heat source, if present.

In one embodiment said electronic feedback mechanism is an ohmic resistor which is connected in series between said substrate and said energy storage element, wherein, preferably, said ohmic resistor is chosen such that it has a resistance in the range of from 0.01-100 kΩ if said substrate has a thickness ≧1 μm, and a resistance >100 kΩ if said substrate has a thickness <1 μm.

In one embodiment said ohmic resistor is chosen in terms of its resistance such that said resistor leads to a reduction of the trans-substrate voltage of at least a factor of 2, preferably a factor of 5 during step d), compared with otherwise identical conditions but in the absence of a resistor.

In one embodiment said ohmic resistor is tunable.

In another embodiment said ohmic resistor has a fixed resistance.

In one embodiment said energy storage element and, preferably also said voltage supply, is connected to said substrate by said electrodes via connections, which, with the exception of said ohmic resistor, if present, have a low impedance which low impedance connections are chosen such in terms of their total impedance value that they do not lead to any significant reduction of the trans-substrate voltage during step d), wherein, preferably said low impedance connections have a total impedance value ≦0.01 M.

In one embodiment said current and power modulating element causes an end of step d) within a user-predefined period after onset of step d), said onset preferably being an increase in electrical current, by a factor of 2, preferably by at least one order of magnitude, or a current value >10 μA, preferably >1 mA.

In one embodiment said energy storage element being electrically connected in parallel to said substrate and said voltage supply is a capacitor or a coil, wherein, preferably, said energy storage element is a capacitor.

In one embodiment said capacitor has a capacity in the range of at least 5 pF/mm substrate thickness, wherein, preferably, said capacitor is connected to said substrate via said current and power modulating element, preferably via said ohmic resistor, such that said electrical energy stored using said capacitor, is dissipated via said current and power modulating element, preferably via said ohmic resistor.

In one embodiment said energy storage element is an intrinsic or intrinsically forming capacitance of said substrate which is the sole energy storage element present or is present in addition to a capacitor as defined above, wherein, preferably, said intrinsic or intrinsically forming capacitance of said substrate is the sole energy storage element present, no electrodes connecting said energy storage element to said substrate are present, and step d) is controlled by appropriate selection of the area of said substrate which area is exposed to the surrounding medium, and/or by appropriate selection of the conductive properties of said medium being in contact with said substrate, said medium being responsible for charge carrier transport during said dissipation in step d), said conductive properties of said medium being defined by pressure, temperature, and composition of said medium, said medium thereby functioning as current and power modulating element.

In one embodiment step b) occurs by the placement of said electrodes at or near said region, preferably by placing one electrode on one side of said substrate and by placing another electrode on another side of said substrate, and by application of said voltage across said electrodes.

In one embodiment said applied voltage is purely DC.

In another embodiment said applied voltage is purely AC.

In one embodiment said applied voltage is a superposition of AC and DC voltages.

Preferably, the frequency of said applied AC voltage is in the range of from 10² to 10¹² Hz, preferably in the range of from 5×10² to 10⁸ Hz, more preferably 1×10³ to 1×10⁷ Hz.

Preferably, said AC voltage is applied intermittently, preferably in pulse trains of a duration in the range of from 1 ms to 1000 ms, preferably 10 ms to 500 ms, with a pause in between of a duration of at least 1 ms, preferably of at least 10 ms.)

In one embodiment said applied AC voltage is used for performing step c).

Preferably, said applied AC voltage has parameters e.g. amplitude, frequency, duty cycle which are sufficient to establish an electric arc between a surface of said substrate and said electrodes, wherein, preferably, said electric arc is used for performing step c).

In one embodiment said applied AC voltage leads to dielectric losses in said region of said substrate, said dielectric losses being sufficient to increase the temperature of said region.

Preferably, the frequency of said applied AC voltage is increased to reduce deviations of the current path from a direct straight line between the electrodes.

In one embodiment the frequency of said applied AC voltage is increased to minimize the possible distance between neighbouring regions, e.g. first, second and further regions.

In one embodiment in step c), heat is applied to said first region of said substrate using a heated electrode or a heating element placed near by the electrode, wherein, preferably, said heated electrode is an electric heating filament and is also used to apply said voltage to said first region in step b).

In one embodiment in step c), heat is applied to said first region of said substrate additionally or only by using an external heat source, such as a laser or other focussed light source.

In one embodiment in step c), heat is applied to said first region of said substrate by applying an AC voltage to said first region, wherein, preferably, said AC voltage is applied to said first region by said electrodes placed on opposite sides of said substrate, preferably at least one electrode being placed on one side of said substrate and at least one electrode being placed on another side of said substrate.

Preferably, said electrodes placed on opposite sides of said substrate are also used for performing step b).

Preferably, said AC voltage is in the range of 10³ V-10⁶ V, preferably 2×10³V-10⁵ V, and has a frequency in the range of from 10² Hz to 10¹² Hz, preferably in the range of from 5×10² to 10⁸ Hz, more preferably 1×10³ to 1×10⁷ Hz.

In one embodiment said first region, and, optionally, said second region and said further regions, is (are) a rod-like structures having a diameter in the range of from 0.01 μm to 200 μm, preferably 0.05 μm to 20 μm.

In one embodiment said electrically insulating or electrically semiconducting substrate is made of a material having a temperature threshold for changes of dielectric and/or optical properties to be introduced, below which no changes in dielectric and/or optical properties can be introduced.

In one embodiment said electrically insulating or electrically semiconducting substrate is made of a material having a saturation temperature above which no further changes in dielectric and/or optical properties can be introduced.

In one embodiment said electrically insulating or electrically semiconducting substrate is selected from a group comprising carbon-based polymers, such as polypropylene, fluoropolymers, such as Teflon, silicon-based substrates, such as glass, quartz, silicon nitride, silicon oxide, silicon based polymers such as Sylgard, aluminium based crystalline materials such as alumina, spinel. Sapphire, as well as ceramics such as zirconia, semiconducting materials such as those semiconducting materials selected from elemental silicon, including doped silicon and crystalline silicon, germanium, compound semiconductors such as gallium arsenide, and indium phosphide.

In one embodiment said substrate is provided in step a) within a medium (solid, liquid or gas) that reacts with a surface of said substrate during steps b), c) and/or d).

The objects of the present invention are also solved by a substrate produced by the method according to the present invention, wherein, preferably, said substrate has at least a first region having altered dielectric and/or optical properties in comparison to other regions where no step d) has taken place, or having an array of regions having altered dielectric and/or optical properties in comparison to other regions where no step d) has taken place.

The inventors have surprisingly found that it is possible to create high aspect ratio domains or regions having altered optical and/or dielectric properties in a dielectric substrate and controlling such process with high accuracy, by a combination of a substrate material having optical and/or dielectric properties that are irreversibly changeable by temporary increases in substrate temperature and a method to introduce heat into the substrate in a highly confined manner. The latter was achieved by an electric discharge through the material that was controlled in terms of power dissipation and duration and was, for highly insulating materials, supported by an initial heat pulse after or during voltage application. The controlled discharge was typically set-up by providing a defined amount of electrical energy to the substrate using a voltage source and preferably an energy storage element, wherein the energy storage element may for example be a capacitor being connected in parallel to the substrate and the voltage source, and dissipating such stored electrical energy in a controlled manner via a current and power modulating element, which may, in the simplest case be an ohmic resistor electrically connected in series between the substrate and the energy storage element. The power modulating element controls the current flowing through said substrate during the dissipation step and thereby also the trans-substrate voltage, as a result of which the local heat production in the substrate is controlled during the dissipation step, and thereby also effectively the size of the thermally altered domain (or region) thus formed is controlled. Because the amount of energy stored across the substrate is finite, due to the finite capacity of the energy storage element, and because the energy storage element has a low impedance, the electrical energy can be dissipated extremely fast. Because in this configuration it is finite, the entire process of dissipation is ended abruptly and fast, as a result of which the substrate is heated locally and consequently the optical and/or dielectric properties of a suitable dielectric material are changed locally. In this configuration the voltage supply itself has very little or no influence on the size of the domain, whereas this size is only determined by the dissipation rate, the amount of electrical energy stored, the trans-substrate-voltage change over time during dissipation U(t), the qualities of the substrate material such as substrate conductivity σ(T) and possibly the medium in contact with the substrate. Although significantly more complex and demanding in terms of precise process control, energy for the electrothermal-focussing process may be provided directly by a voltage source having an appropriate impedance to maintain the required trans-substrate voltage(s) during the process and which has to allow for a very fast (usually less than or equal 10⁻⁶ sec, preferably less than or equal 10⁻⁸ sec) control/adjustment of the trans-substrate voltage. In order to present the basic method and device in full clarity a finite energy source is chosen as example energy source—which may throughout all descriptions be replaced by the aforementioned voltage source having an appropriate impedance to maintain the required trans-substrate voltage(s) during the process. In the method according to the present invention it is possible to introduce regions having altered optical and/or dielectric properties, without the concomitant formation or introduction of a physical hole or channel in said substrate.

The amount of energy that is stored across the substrate is chosen such that an electrothermal focussing process may take place to the extent that the material within the substrate is heated locally without being ejected from the substrate to a significant extent. The term “without being ejected from the substrate to a significant extent”, as used herein in connection with substrate material in a region, is meant to refer to a situation wherein, upon performing the method according to the present invention on a substrate, such substrate does not change its overall physical dimensions, and it does not change its volume and/or weight, upon performing the method according to the present invention. The term “volume” as used in this connection is meant to refer to the space occupied by substrate material. In preferred embodiments according to the present invention, the substrate, prior to performing the method thereon, may have uniform optical and/or dielectric properties throughout, and, upon performing the method according to the present invention, in defined regions, the optical and/or dielectric properties are changed, as a result of which there are “domains” (or “regions”) of altered optical and/or dielectric properties in comparison with the remainder of the substrate. The term “electrothermal focussing” (also sometimes abbreviated as “ETF”) is meant to describe a controlled dielectric breakdown process which is focussing, in terms of energy dissipation and temperature increase, towards the center of the breakdown path across the substrate.

The term “electric arc”, as used herein, is meant to signify a plasma resulting from a current flowing through usually non-conductive media such as air or another gas. The arc may produce high temperatures sufficient to for example melt glass.

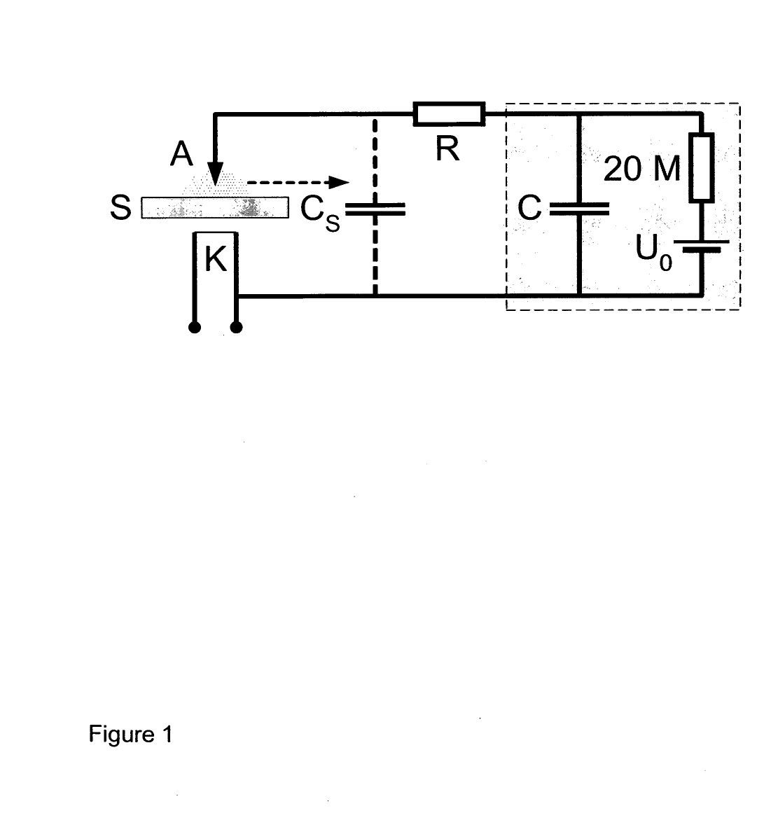

The term “being connected to a substrate” when used here in conjunction with an element such as a voltage supply, an energy storage element, a capacitor, etc. does not mean that there must be a physical contact between the substrate and such element; rather this refers to an arrangement wherein such connection enables the flow of current through such substrate if the atmosphere around the substrate or between the element and the substrate has been sufficiently ionised (see also FIG. 1 for such connection). A “connection” may therefore e.g. refer to a scenario wherein an energy storage element and/or a voltage supply, is connected to said substrate by electrodes, which electrodes either touch said substrate or touch a medium, said medium being in contact with said substrate, wherein said medium is a liquid or gaseous medium which is electrically conducting or can be made electrically conducting, e.g. by ionisation.

The term “aspect ratio” is meant to characterize the ratio between the depth and diameter of a region or domain in accordance with the present invention. Regions having a high aspect ratio are regions having a small diameter compared to their depth or height.

The term “optical properties”, as used herein, is meant to refer to any material property impacting the transmission, reflection, refraction, dispersion, filtering, polarization, optical isotropy/anisotropy etc. of light interacting with the substrate. The term “change in optical properties”, as used herein, is meant to refer to an irreversible change of one or more of the afore-mentioned material properties caused by a temporary increase in the temperature of a material/substrate which allows for such changes. The term “light”, as used herein, is meant to refer to light/electromagnetic radiation ranging from x-rays to infra-red, i.e. λ≈1 nm-30 μm 1 μm=1 um=10⁻⁶m).

The term “dielectric properties”, as used herein, are meant to refer to a material's dielectric constant, permittivity, dielectric strength, etc.

In a further aspect, the present invention relates to a method of introducing a structural change, such as a transition from a crystalline structure to an amorphous structure, in a substrate or a region thereof, said method comprising the steps:
a) providing a substrate which is electrically insulating or semiconducting at room temperature, and placing it between at least two electrodes connected to a user-controlled voltage supply,
b) applying, by means of said user-controlled voltage supply, a voltage of user-defined magnitude across a region of said substrate, said voltage being sufficient to give rise to an increase in electrical current through said substrate or said region, thereby applying a defined amount of electrical energy to said substrate,
c) optionally, applying additional energy, preferably heat, to said substrate or said region so as to increase the temperature and the electrical conductivity of said substrate or said region so as to initiate the current flow in step b), said additional energy, preferably heat, originating either from an additional energy or heat source or from components of said voltage applied in step b),
d) dissipating said electrical energy applied in step b) in said substrate,
   wherein step d) is controlled solely by (i) the user-defined magnitude of the applied voltage of step b), (ii) a user-defined period of time of step b), (iii) an impedance of said voltage supply, or (iv) any combination of (i)-(iii), and
   wherein said electrical energy applied in step b) is not sufficient to generate a through hole or through channel in said substrate in performing step d), but is sufficient to change the structure in said substrate region, wherein, preferably, step d) changes the structure in said substrate region by heating and/or melting the material present in said substrate region, and wherein such change in structure makes said substrate region more amenable to treatment by an ablating step e) in which said substrate including said substrate region is exposed to an ablating environment such as an etching agent.

In one embodiment, said electrical energy is not sufficient to cause an ejection of material from said substrate region.

As used herein, the term “to change the structure in a region of a substrate” refers to any structural change applied to the substrate material present within said region which results in altered properties, preferably altered optical or dielectric properties, of the substrate material within said region, without the substrate material actually being removed or ejected from said region. For example the change from a crystalline to an amorphous structure would exemplify such structural change, whereas a removal of substrate material from said region resulting in a through-hole or other through-connection would not exemplify such structural change.

In one embodiment, said control of step d) by controlling (i), (ii), (iii) or (iv) is achieved using a programmed or feedback circuit analysing the trans-substrate current or trans-substrate voltage over time.

In one embodiment, said control of step d) by controlling (i), (ii), (iii) or (iv) is achieved by solely user-defining (i), (ii), (iii) or (iv) and without using a programmed or feedback circuit analysing the trans-substrate current or trans-substrate voltage over time.

In one embodiment, said user-defined magnitude of voltage is in the range of 10 V to 10⁶ V, preferably from 10² V to 3×10⁵ V, more preferably from 10³ V to 30×10³ V, and most preferably from 2×10³ V to 15×10³ V.

In one embodiment, said user defined period of time is in the range of from 1 ms to 5000 ms, preferably from 10 ms to 2000 ms, more preferably from 10 ms to 1000 ms, and even more preferably from 10 ms to 500 ms.

In one embodiment, said impedance of said voltage supply is an impedance >1 Ohm, preferably >10 kOhm, more preferably >100 kOhm, and, even more preferably >1 MOhm.

In one embodiment, said impedance is in the range from 1 Ohm to 1 GOhm, wherein, preferably, said impedance is variable within said range during performance of said method.

In one embodiment, said electrically insulating or semiconducting substrate is made of a material selected from a group comprising carbon-based polymers, such as polypropylene, fluoropolymers, such as Teflon, silicon-based substrates, such as glass, quartz, silicon nitride, silicon oxide, silicon based polymers such as Sylgard, semiconducting materials such as elemental silicon, including doped silicon and crystalline silicon, germanium, compound semiconductors, such as gallium arsenide, indium phosphide, as well as aluminium based crystalline materials such as alumina, spinel, sapphire, as well as ceramics such as zirconia.

In one embodiment, step d) is initiated by either (i) applying a voltage of user-defined magnitude across a region of said substrate in step b), said user defined magnitude of voltage being sufficient to give rise to an increase in electrical current through said substrate or said region and a subsequent dissipation of said electrical energy in said substrate, (ii) applying a voltage of user-defined magnitude across a region of said substrate in step b), said user defined magnitude of voltage not being sufficient to give rise to an increase in electrical current through said substrate or said region and to a subsequent dissipation of said electrical energy in said substrate, and reducing the distance between each of the electrodes and the substrate and, optionally, contacting said substrate with said electrodes, (iii) performing step c), or (iv) a combination of (i)-(iii).

In one embodiment, step c) is omitted, wherein, preferably, said substrate is a substrate having an electrical resistivity ≦10⁹ Ωcm at room temperature.

In one embodiment, said substrate is electrically semiconducting at room temperature and is preferably made of a semiconducting material selected from elemental silicon, including doped silicon and crystalline silicon, germanium, compound semiconductors such as gallium arsenide, and indium phosphide.

In another embodiment, step c) is performed, wherein, preferably, step c) is performed using an additional energy source which is selected from a heated electrode, a heating element, a laser, a focussed light source, a UV light source and a gas flame.

In one embodiment, said additional energy source is a laser which preferably has a wavelength in a wavelength range that is at least partially absorbed by said substrate.

In one embodiment, the site of application of additional energy in step c) determines the region of said substrate in which said structural change is introduced.

In one embodiment, said substrate which is electrically insulating at room temperature or electrically semiconducting at room temperature is provided in step a) having at least one electrically insulating layer attached, wherein, preferably, said electrically insulating layer is solid, liquid or gaseous at room temperature.

In one embodiment, said electrically insulating layer is gaseous at room temperature and is not air.

In one embodiment, said electrically insulating layer has an insulating region which is adjacent to and in contact with said substrate region in which substrate region a structural change is to be introduced, and is preferably effectively reducing the voltage across the substrate (shielding effect) without lowering the voltage between the electrodes, and wherein step c) is performed such that in said electrically insulating layer the electrical conductivity is raised in said insulating region so as to reduce its voltage shielding effect and augmenting the trans-substrate voltage in said substrate region.

In one embodiment, said electrically insulating layer has an insulating region which is adjacent to and in contact with said substrate region in which substrate region a structural change is to be introduced, wherein step c) is performed such that said electrically insulating layer, if provided as a solid in step a), is liquefied in said insulating region, or is performed such that said electrically insulating layer, if provided as a liquid in step a), is partially evaporated in said insulating region,

and wherein during step d), said electrically insulating layer is partially displaced in said insulating region, through the dissipation of said electrical energy, and wherein, after step d), said gaseous, liquefied or partially evaporated electrically insulating layer flows onto said substrate region and covers it.

In one embodiment, said electrically insulating layer is attached to said substrate in such a manner that it covers said substrate in step a) or is covered by said substrate in step a), and said substrate region lies opposite said insulating region.

In one embodiment, the insulating layer reduces the voltage across the substrate by formation of an internal counter electric field due to electrical polarization of the insulating layer material.

In one embodiment, step c) is performed by directly heating the insulating layer such as through absorption of laser radiation of a wavelength absorbed by the insulating layer.

In one embodiment, step c) is performed by indirectly heating the insulating layer by heating the attached substrate and utilizing heat transfer from the heated substrate to the attached insulating layer.

In one embodiment, said electrically insulating layer is made of a material which is solid and electrically insulating at room temperature and preferably selected from wax, in particular paraffin wax, rubber, hot melt adhesive, poly(styrene-butadiene-styrene), and polyurethane.

In one embodiment, said electrically insulating layer is made of a material which is liquid at room temperature, and which is electrically insulating at room temperature or polar or both and is preferably selected from dodecane, paraffin, water, or high viscosity water based liquids such as Ficoll™ solution or honey like liquids.

In one embodiment, said electrically insulating layer is made of a material which is gaseous at room temperature and is preferably selected from SF₆, Ar, N₂, CO₂.

In one embodiment, said substrate is electrically insulating at room temperature and is preferably made of a substrate material selected from glass, quartz, diamond, alumina, sapphire, aluminium nitride, zirconia, and spinel, more preferably quartz and glass, wherein, preferably, said substrate has an electrical resistivity >10⁹ Ohm cm at room temperature.

In one embodiment, said electrically insulating layer, if present, is made of a material which is solid and electrically insulating at room temperature and is preferably selected from paraffin wax, rubber and hot-melt adhesive.

In one embodiment, step c) is performed using a laser, preferably having a wavelength in a wavelength range which is at least partially absorbed by said substrate material and/or said insulating layer, if present.

In one embodiment, said substrate is electrically semiconducting at room temperature and is preferably made of a substrate material selected from elemental silicon, including doped silicon and crystalline silicon, germanium, compound semiconductors such as gallium arsenide and indium phosphide.

Preferably, said substrate has an electrical resistivity ≦10⁹ Ohm cm at room temperature.

In one embodiment, said electrically insulating layer, if present, is made of a material which is liquid and electrically insulating at room temperature, or polar or both and which is preferably selected from dodecane, paraffin, water, honey, or is made of a material which is solid and electrically insulating at room temperature and which is preferably selected from paraffin wax and hot-melt adhesive.

In one embodiment, step c) is performed using a laser, preferably having a wavelength in a wavelength range which is at least partially absorbed by said substrate material and/or said insulating layer, if present.

In one embodiment, step c) is performed such that heating of the insulating layer necessary for a electric field reduction across this layer necessary to initiate step b) and d) is leading to a significant increase in temperature of the substrate leading to a significant change of its temperature dependent mechanical parameters such as hardness and brittleness.

In one embodiment, steps a)-d) are performed once, such that a first structural change is generated in the first substrate region, thereafter the substrate is moved by a defined distance, and steps b)-d) are performed a second time such that a second structural change is generated in a second substrate region, wherein, preferably, steps b)-d) are performed n times, such that an array of n structural changes is generated in said substrate, n being an integer >1.

In one embodiment, the method according to the present invention further comprises step
e) exposing said substrate including said substrate region to an ablating environment, such as an etching agent.

In one embodiment, said substrate is electrically semiconducting at room temperature and is preferably made of a semiconducting material selected from elemental silicon, including doped silicon and crystalline silicon, germanium, compound semiconductors such as gallium arsenide, and indium phosphide.

In one embodiment, said ablating environment is an etching agent and preferably is an etching agent selective for semiconducting materials, and is more preferably selected from KOH, SF₆, tetramethylammonium hydroxide (TMAH), ethylenediamine pyrocatechol (EDP), hydrazine, and HF.

In one embodiment, said ablating environment is created by a reactive ion etching process.

In one embodiment, said ablating environment is SF₆ used for etching.

In one embodiment, steps b) and d) are performed a number of times n, n being an integer >1, thereby applying electrical energy to a first, second, third, . . . n-th region of said substrate, and thereby changing the structure in said first, second, third, . . . n-th region of said substrate.

In one embodiment, the method according to the present invention further comprises step e), wherein step e) is performed once after steps b) and d) have been performed a number of times n, thereby generating an array of n through holes or n through channels in said substrate.

In one embodiment, said substrate is elemental silicon and said etching agent is selected from KOH, TMAH, SF₆.

In one embodiment, a crystalline substrate is chosen having crystal orientation reducing the etch rate parallel to the substrate surface compared to differently oriented substrates.

In one embodiment, a crystalline substrate is chosen having crystal orientation reducing the etch rate perpendicular to the substrate surface compared to differently oriented substrates, such as a <111> silicon wafer in KOH.

In one embodiment, the substrate is coated with a protective layer not or less etched by an etching agent than the substrate itself and which during performing step a)-d) is fully or partially removed or structurally altered so as to allow etching only at the region(s) where step d) has been performed.

In one embodiment, the method according to the present invention uses the insulating layer, as defined above, as protective layer.

The objects of the present invention are also solved by a structural change or an array of structural changes in a substrate, produced by the method according to the present invention.

In a first aspect the present invention relates to a method of introducing a structural change such as a transition from a crystalline to an amorphous microstructure, in a substrate located between (at least) two electrodes which are connected to a controlled voltage supply. Energy is provided by the voltage source which is fully or in part locally dissipated within the substrate controlled through the voltage magnitude and/or source impedance and the time over which the voltage is applied. In general the voltage can be a function of application time V(t), which changes due to changes of the electric circuit during application and/or a programmed and/or feedback circuit analysing the substrate current and/or voltage. During voltage application the energy dissipation inside the substrate is controlled so as to achieve local changes in the physico-chemical properties of the substrate such as the transformation of crystalline regions into amorphous regions by raising T in the dissipation region up to the respective melting or transition T. The process may be explicitly stopped before any topological changes such as the formation of holes take place. To initiate the dissipation process in the first place it may be necessary to supply auxiliary heat to the modification region so as to locally increase the temperature and therefore conductivity of the region as already disclosed and outlined in WO2005/097439 and PCT/EP2008/009419 However, the placement of the auxiliary heat allows to define the region which will be modified.

For the application of voltages to substrates in general, the nature and dimensions of substrates and structures, reference is made to WO2005/097439 and PCT/EP2008/009419, which are hereby incorporated in their entirety by reference thereto.

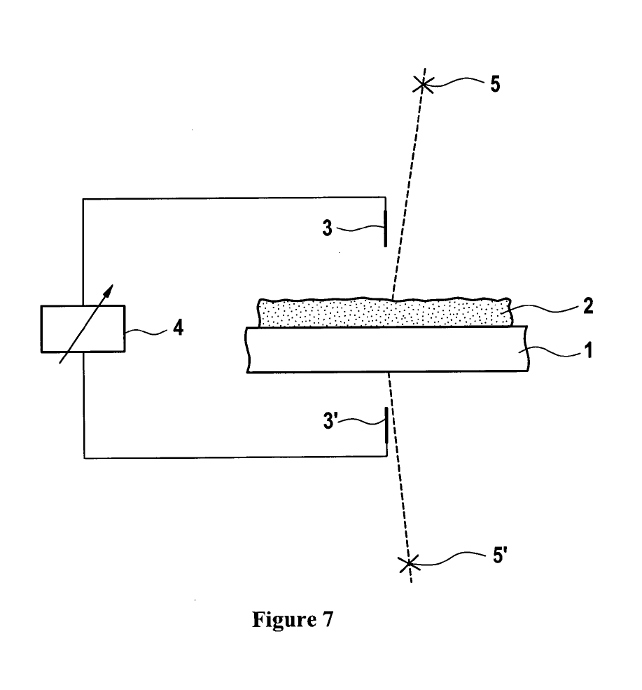

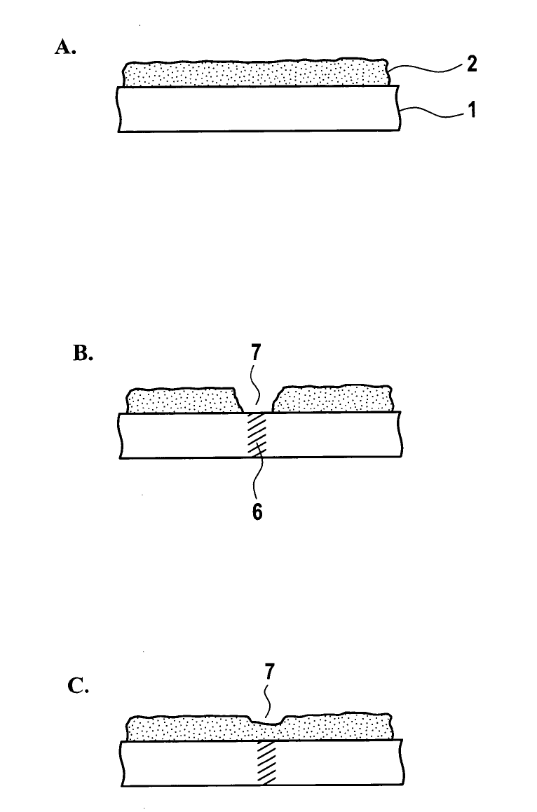

For certain substrates, e.g. such having a high conductivity or such having already holes which cause the applied voltage to short-cut, the substrate (1) is attached to one or two insulating layers (2) (FIG. 7). These layers effectively shield the applied voltage (electrodes 3, 3′, voltage supply 4, laser 5 or 5′, in FIG. 7) from the substrate, e.g. by having a very high resistivity or by the induction of a counter field within them (as is the case when using polar substances such as water). In other words, part or in some cases most of the voltage applied via the electrodes creates an electric field across the insulating layer thereby reducing the electric field inside the substrate, which can effectively lead to a dramatic reduction of field inside the substrate for a constant voltage across the electrodes, thereby preventing discharges at voltages which would otherwise initiate an electric break-down within the substrate. To initiate the energy dissipation within the substrate the insulating layer has to be raised in conductivity at the site where the attached substrate is to be modified. This can be done upon irradiation (e.g. UV) or heating of this site using e.g. a laser. After modification of the substrate, which may involve the formation of holes as e.g. described in WO 2005/097439 or PCT/EP2008/009419, or the local change of the physico-chemical properties as described before, the insulating layer, which has been opened and melted and/or evaporated in parts, may be closed again to proceed with the modification of additional regions within the substrate. Using e.g. fluid or gel like insulating layers such as pure water or hydrocarbons (wax, dodecane, paraffin, . . . ) the insulating layer may close by itself e.g. due to surface tension or substrate adhesion. Solid layers may be closed using heat induced reflux which may be initiated with application of the auxiliary heat, the energy dissipation process itself or by a subsequent heating step after modification. The combination and repetition of the described steps allows for multiple such substrate structure changes in close spatial proximity to each other e.g. organized in form of an array.

In a further device and method according to the present invention the forgoing methods and devices are used to introduce structural changes within the substrate that modify the physico-chemical properties at the dissipation site(s) in such a way that exposure of the substrate to ablative environments such as an etching solution or reactive ion plasma (RIE) leads to a differential material ablation in the modified and unmodified regions. If the modified region is attacked more strongly hole and well like structures will result, in the opposite case columns of modified regions will stick out of the ablated substrate. The etching step may also be performed to modify structures produced according to WO 2005/097439 and PCT/EP2008/009419 as the heated and expelled material has for certain materials new physico-chemical properties that allow e.g. the ablation of redeposited material or the increase of the produced hole (diameter). The fact that such etching step results in a preferential ablation/removal of material from the substrate region where energy dissipation has previously taken place is a proof of the presence of altered structural properties in such substrate region. An example are holes produced in Si wafers as described and subsequently exposed to a warm solution of 50% KOH (e.g. at 80° C.). It should be noted that the term “elemental silicon” or “silicon” includes crystalline (monocrystalline or polycrystalline) silicon such as is used in silicon wafers. The term also includes doped silicon.

To protect the non-modified substrate better during the etching step, effectively allowing to immerse the entire wafer or one side of the wafer to the etching agent, the substrate may be covered with a protective layer. This usually thin layer (typically <10 um) is removed or altered at the modification region(s) providing only there access of the etching agent to the substrate. An example is a Si3N4 layer of typically <1 um thickness on an Si wafer. Using subsequently KOH based etching media the Si wafer is not etched due to the nitride layer—except where energy was dissipated.

In order to achieve optimal etching results, such as a reduced etch rate perpendicular the axis of the formed structure or a reduced/increased etch rate perpendicular to the substrate surface the crystal lattice orientation of the substrate may be selected accordingly (where applicable). An example is the usage of <111> Si wafer treated with KOH solution to reduce the etch rate perpendicular to the wafer surface thereby further increasing the etch rate differences between modified and unmodified regions.

The combination of ablation and micro-structural substrate changes in the formation of holes has, because internal pressure during such step is smaller compared to a step where material is actively expelled from the forming structure, the advantage that breakages or deformation of crevices are less likely to occur. Moreover, subsequent polishing steps which might otherwise have been necessary can be avoided because the conditions applied to the substrate are generally gentle enough and no depositions of substrate material on the substrate surface occur.

According to the present invention, the inventors have established devices and methods to apply electrical energy to a substrate which electrical energy is not sufficient to cause the formation of a through hole or through channel in the substrate but which makes the structure of the region in which the electrical energy is applied, more amenable to a subsequent etching step. The fact that such etching step then results in a preferential ablation/removal of material from the substrate region where energy dissipation has taken place is a proof of the presence of altered structural properties in such substrate region. In accordance with embodiments of the present invention, the substrate is placed between two electrodes connected to a voltage supply capable of causing an electrical discharge through the substrate upon (1) increase of the field strength between the electrodes by e.g. increase in voltage (typically 1000-300 000 V), (2) closing of the electrode distance or (3) local heating of the substrate or (4) local heating of an insulating layer attached to the substrate. The discharge and therefore the voltage supply is controlled so as to provide an electrical power P(t) over a time interval Dt. The interplay between power and time thereby determines the T-profile building up inside the substrate. Without wishing to be bound by any theory the present inventors believe that this method, in significantly heating the substrate in a defined substrate region, changes the structure of said region. Again, without wishing to be bound by any theory, the present inventors believe that a less ordered structure is generated by such heating procedure. For example, in substrates which are crystalline such as wafers used for chip manufacturing, the method is believed to lead to an amorphous structure upon raising the temperature locally to or close to the melting point. The region in which said electrical energy has been applied, therefore becomes more amenable to etching, and subsequently gets etched selectively upon application of an etching agent. An example is the process applied to silicon in <100> orientation with >10 Ohm cm conductivity and 0.25 mm thickness, electrode spacing between substrate and electrode 0.5 mm each, V=2000V, C ca 1 nF and Dt<100 msec produces holes of ca 30-100 um in diameter upon etching with 50% KOH solution at 80° C. In preferred embodiments of this aspect according to the present invention, the step b) and d) in which electrical voltage is applied to a region of a substrate and consequently electrical energy locally dissipated, is repeated n-times, n being an integer >1, thus leading to an array of n regions having altered structures; optionally thereafter an etching step may be performed, thus leading to the generation of n through hole structures or through channel structures in the substrate. This aspect according to the present invention is particularly suitable for the formation of arrays of structures in electrically semiconducting substrates.

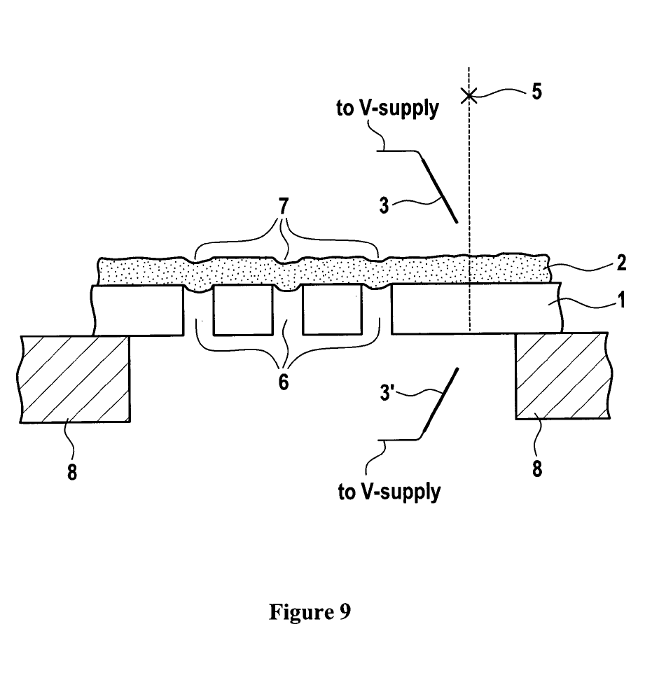

In embodiments according to the present invention, the inventors have also introduced an insulating layer in methods of generating structures or structural changes in substrates using electrical energy. The step is important for rather conducting substrate materials such as semiconductors as well as arrays of holes in all substrates where in the first case the entire wafer and in the second the pre-existing holes have to be shielded from the applied voltage thus that only the part of the substrate to be modified is exposed to the electrical field so as to define accordingly this region as the discharge place (FIG. 9). The insulating layer may consist of gaseous, such as SF6, liquid such as paraffin and water as well as solid materials such as wax. The layer must shield sufficiently from the applied voltage so as to avoid discharges without further invention. This may occur purely through insulating, that is properties of high resistivity of the insulating layer as well as shielding properties where the applied voltage induces a counterfield within the insulating layer, which is usually the case in polar materials such as water. The actual discharge process, that is the dissipation of energy within the substrate is initiated upon local raise in conductivity of the insulating layer, e.g. by heating a defined region which lies opposite and adjacent to the region of the substrate, in which the structure is to be generated. Such defined region in the insulating layer, herein also sometimes referred to as an “insulating region”, allows after the change in resistivity or change in the dielectric properties such as the dielectric constant, that a current starts flowing through it and consequently through the adjacent region of the substrate, thereby effectively determining the region of the substrate where energy is dissipated. In preferred embodiments, such insulating region becomes liquid or melts and can be subsequently fully or in part evaporated when the generation of the structure through application and subsequent dissipation of electrical energy to the substrate occurs. However, since the insulating layer typically is still liquid or molten around said region, it may reflow into the generated structure and thereby closes and/or at least partially fills it. In one embodiment after performing step d), there may be a further step f) in which additional energy, preferably heat, is applied to said insulating region, so as to melt or liquefy said insulating layer again or to keep the insulating layer liquid or molten. Preferred means of applying additional energy, either in step c) or step f) are selected from a heated electrode, a heating element, a laser, a focussed light source and a gas torch. In preferred embodiments, the means for heating is a laser. The laser can heat the insulating layer directly (beam is directly absorbed) or indirectly (the beam is absorbed by substrate and heat is transferred to the insulating layer by heat conduction), or a combination wherein both layers absorb partially. The selection of a specific laser depends on the substrate and insulation material. Examples are CO₂-laser having a wavelength of 10.6 μm. Other preferred lasers are lasers having a wavelength in the range of from 800 nm to 1300 nm. It should be noted that the laser wavelength is also chosen such that it is absorbed by the insulating layer and heats it, and/or it is absorbed by the substrate which heats the insulating layer. This allows a heating of the insulating layer. Absorption may be 100% or less, i.e. substantially all or fractions of the incident radiation is absorbed by the substrate or the insulating layer or both. As used herein, the term “is at least partially absorbed” is meant to refer to any scenario wherein the substrate and/or the insulating layer absorbs 0.1% to 100% of the incident radiation. As used herein, the term “insulating layer” refers to a layer that is attached to the substrate, preferably in a side-by-side-manner, such that the insulating layer and the substrate are adjacent and opposite to each other. In this arrangement the region, in which a structure is to be generated in the substrate is also sometimes referred to as a “substrate region”, and the corresponding region in the insulating layer lying opposite such substrate region, is also referred to as “insulating region”. Effectively, such insulating region lies on top of or underneath said substrate region. In one embodiment, the insulating region and the substrate region are of the same size. In another embodiment, the insulating region is 5% or more, such as 10%, 15%, 20%, 25%, 30%, . . . , 100%, 200%, 300%, 400%, . . . 1.000%, 2.000%, 3.000%, . . . , 10.000% or more larger in area than the substrate region.

The use of an insulating layer in the aforementioned sense in a method of generating a structure has several advantages: It avoids short circuits occurring if several structures are generated in the substrate, because once a structure, such as a hole, is formed, it is subsequently closed and therefore unavailable as a potential by-path for electrical energy to be dissipated when subsequent structures are to be generated. Moreover, the insulating layer also provides structural support to the substrate and stabilizes it. In some embodiments there may be more than one insulating layer, for example one insulating layer on either side of the substrate. Furthermore, the use of an insulating layer allows the production of several structures in a substrate next to each other, such that an array of structures in a substrate is formed. The method according to the present invention is therefore amenable to mass-production and also allows the formation of structures which are close to each other. For example, in a substrate made of an electrically semiconducting material, such as silicon wafers of >100 Ohm cm and <0.5 mm thickness, the structures of e.g. 30 um diameter formed therein using a insulating layer in accordance with the present invention, may be as close to each other as 60 μm.

For certain substrate materials, in particular low conducting materials such as glass, the insulating layers and the substrate may have to be heated to initiate the energy dissipation process. Therefore, the method/device described for microstructural changes as well as the method/devices disclosed in WO2005/097439 and PCT/EP2008/009419 may be combined with it so as to not only heat the insulating layer but effectively raising the temperature of the underlying substrate region to initiate the energy dissipation step. This becomes of importance when producing arrays in insulating materials where the insulating layer shields pre-existing holes and the heating is necessary to not only make the insulating layer more conductive but also the substrate in order to initiate the discharge process. However, pre-heating of the substrate prior to the actual energy dissipation process in step d) taking place may also be employed to change mechanical substrate parameters such hardness and brittleness and thus to reduce or avoid the formation of cracks within the substrate. Finding an optimum for this pre-heating requires a certain ratio between heat absorption of the substrate and the insulating layer. Typically, this ratio is controlled and can be determined by choosing the wavelength of the initiation laser in step d) and the substrate side from which heat is applied.

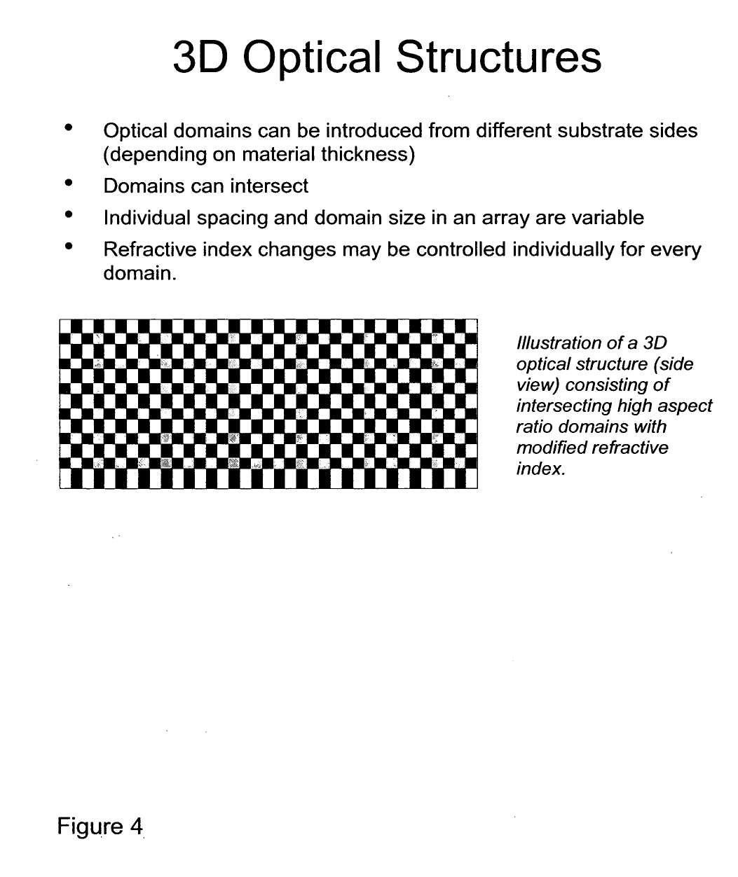

In accordance with the control of the energy dissipation aspect of the present invention, the inventors have surprisingly found that it is possible to generate structures, preferably holes or cavities or channels or recesses in a substrate using electrical energy which is applied to the substrate, wherein the amount of energy is solely defined by the voltage applied across the electrodes and the time over which such voltage is applied. Other parameters to control and features to control them are no longer necessary. In previous patent applications, the overall amount of energy that is applied to the substrate had been limited by an appropriate capacitor, or the rate of dissipation of the energy stored across the substrate had been controlled by an ohmic resistor. In the present aspect of the method according to the present invention, these features are no longer necessary, and the amount of electrical energy applied can be defined only by the defined duration of step b) and the defined voltage applied in step b). This makes the process very versatile and very easy to perform. It is particularly suitable for semiconducting substrates such as standard silicon wafers, wherein preferred voltage ranges are from 100 V to 10⁵ V, more preferably 1.000 V to 15.000 V, and preferred durations of step b) are 10 ms to 2 s, preferably 50 ms to 500 ms. Furthermore, especially with semiconducting substrates, it is no longer necessary to use additional energy, such as heat to be applied, in order to generate the structure (FIG. 4). According to this aspect, the method according to the present invention can be performed without a source of additional energy, such as heat, for example a laser, and the amount of electrical energy is solely determined by the applied voltage and the duration of step b), which parameters come to lie in the ranges of 100 V-100.000 V, preferably 1.000 V to 15.000 V, and 10 ms to 2 s, preferably 50 ms to 500 ms. The size of the structure generated is only dependent on these two parameters. Accordingly, the use of an additional energy source, such as a laser in these embodiments is no longer necessary.

In yet a further aspect according to the present invention, the present invention relates to individual structures in substrates, such as holes, cavities, channels etc. in substrates, as well as arrays of such structures in substrates, produced by any of the aforementioned methods according to the various aspects.

Using the method according to the present invention, structures and arrays of structures may be formed having dimensions in the pm range or even below.

More specifically, using the method and the device according to the present invention, the controlled formation of holes 0.1-10 μm in diameter with aspect ratios ≦330 and arranged in arrays has been achieved in amorphous dielectrics, such as glass and fused silica, by fast resistive heating. A strongly focussed hyper-exponential temperature increase inside the dielectric led to fast material melting and evaporation. Time intervals between melting and evaporation were estimated ˜10⁻¹¹ s with power densities reaching 100 W/μm³. The hole size was a function of the substrate conductivity σ(T) and the applied voltage U(t) and characterized by a high reproducibility. The exemplary application of large aspect ratio holes in electroosmotic pumps and low noise ion channel measurements was demonstrated.

In the method according to the present invention, the heat produced during the dielectric breakdown is used to locally change the dielectric and/or optical properties of a suitable substrate in defined regions. Without wishing to be bound by any theory, the present inventors have shown that the heat produced during dielectric breakdown is usually relatively evenly distributed along the current path which, in turn, will lead to regions (or domains) having constant optical and/or dielectric properties when viewed along the direction of the originally induced dielectric breakdown path. Such regions or domains in many instances have a rod-like or cylindrical shape. Such regions or domains may also be produced with very high aspect ratios, i.e. aspect ratios ≧100. Since the width of the breakdown area and therefore the temperature profile which is the temperature profile perpendicular to the breakdown direction, is easily controlled, for example in the embodiment involving a resistance R by adjusting such resistance or the trans-substrate voltage, the width of the region having altered optical and/or dielectric properties may be easily adjusted. Also, using substrate materials whose optical and/dielectric properties are gradually changed with temperature, domains with gradients in these properties reflecting the temperature profile during the electric discharge may produced. Because the latter is controlled, domains with controlled gradients in the optical properties may be produced. Furthermore, stopping the discharge process at predetermined temperatures inside the discharge path allows the control over the degree/magnitude to which the optical properties in these domains are changed. In order to achieve the dielectric breakdown in accordance with the present invention, it is important to avoid a substantial ejection of material from the substrate and therefore, the amount of energy stored across the substrate must be strictly controlled, such that the entire process is ended before any or any substantial ejection of material can take place. This can for example be achieved by limiting the energy available for a dielectric breakdown by using a capacitor as energy source which is sufficiently discharged before a material ejection occurs. The process may also be ended by a trigger circuit monitoring the substrate current during breakdown and reducing the trans-substrate voltage sufficiently before ejection or any substantial ejection of material occurs or when a predetermined temperature inside the substrate is reached.

It should also be noted that the dimensions of the region (or domain) formed or introduced in said substrate are solely determined by the electrical parameters, such as the amount of stored electrical energy, electrical current being supplied to said substrate during dissipation of said electrical energy, and current and power modulating element, and by the material parameters, such as the material of the electrically insulating substrate, e.g. its density, specific heat capacity, heat conductivity and the electrical conductivity and its temperature dependency, whereas the dimensions of the region are independent of the additional energy or heat source and its parameters. Consequently such additional energy or heat source has to fulfil only minimum requirements, namely that it be capable of raising the conductivity of the substrate locally to enter the discharge process if the applied trans-substrate voltage is insufficient to initiate the discharge process through the substrate on its own. Such additional energy or heat source is required for many high dielectric strength materials such as glass and fused silica and is usually optional for materials such as polymers. In any case, the auxiliary heat source may be used to define precisely the location of the discharge process on the substrate by selectively raising the conductivity of the region (or part thereof) to be modified. Due to the self-focussing nature of the dissipation process in step d), the dimensions of the structure are therefore only dependent on the electrical parameters and the material parameters and not on the additional heat or energy source, provided that such heat or energy source is capable of raising the electrical conductivity of the substrate locally. It should also be noted that such local increase in electrical conductivity does not finally determine the dimensions of the region formed.

Using the method according to the present invention, regions within a substrate may be formed having dimensions in the gm range and below.

More specifically, using the method and the device according to the present invention, the controlled formation of regions with altered optical and dielectric properties and 0.1-10 μm in diameter with aspect ratios >100 has been achieved in various dielectrics, ranging from polymers to amorphous dielectrics such as glasses, by electrothermal focussing. A fast and self-focussing temperature increase within the discharge path led to the modification of dielectric/optical substrate material properties in this region. The size of the transformed region (or domain) appeared to be a function of the substrate conductivity σ(T) and the applied substrate voltage U(t), the latter being related to the trans-substrate current by Ohm's law, and was characterized by a high reproducibility.

The properties and size of the formed domain are a function of both, the substrate current and the time over which this current is provided, reflecting the temperature distribution during the transformation/discharge process. The width of a domain is increased by prolonged current injection to the substrate. Adjusting the current magnitude and its application time, even a quasi steady-state temperature distribution can be created inside the substrate, defined by the ratio between dissipated power and heat conducted within and at the surface of the substrate, allowing for the defined and reproducible formation of domains. To achieve specific radial transformation T-profiles, the time over which a current is injected as well as its magnitude (time course) are controlled. As an example, injection of a relatively small current over a long time (mA range and below, over several 10 msec in a glass like substrate of >100 μm thickness) will produce rather wide T-profiles with relatively low core temperatures. The opposite is achieved with higher currents for significantly shorter times, thereby reducing temperature spreading (conduction) into the discharge path surrounding substrate. Adjusting the relation between current magnitude, its change over time and the overall application time is important for the formation of specific domain properties. It is also possible to form microlenses in the substrate using the method according to the present invention. These microlenses, i.e. regions acting as a lense and having dimensions in the range of 0.1 μm to 100 μm, are created by creation of a gradient refractive index in the first region extending from the (flat) surface or in a concentrical arrangement around the path of energy dissipation, or by creation of a bump/lense shape geometry on the surface or by a combination of the foregoing.

Domains having altered optical and/or dielectric properties in comparison to the remainder of the substrate may be tightly packed on a single substrate in accordance with the present invention, e.g. in a periodic manner such as to modify the propagation and interference of light in a specific way (S. John, “Strong Localization of Photons in Certain Disordered Dielectric Superlattices”, Phys. Rev. Lett. 58, 2486 (1987)). For the latter the distance between domains would be in the range of the wavelength (or half-wavelength) of the light to influence. This is possible because bypass-paths of the region to modify by the electric discharge are avoided which would otherwise occur if through-holes were formed and if these holes were too close to the region exposed to the process-inherent trans-substrate voltage. The regions having altered optical and/or dielectric properties in accordance with the present invention can be easily produced in parallel, that is by concurrent dielectric breakdowns on a single substrate. In order to do this, for example, multiple electrodes with voltages not referenced to each other are preferred to avoid interferences. In these embodiments, the dissipation of the energy stored across the substrate may be initiated by generation and projection of an optical pattern of light spots on the substrate produced for example by a strong laser, such as a CO₂-type laser. In such an optical pattern, each spot initiates the formation of a region having altered optical and/or dielectric properties, by subsequent dielectric breakdown.

Likewise, in one embodiment, regions having altered optical and/or dielectric properties, can be manufactured from different sides of the substrate enabling the production of a complex, e.g. 3-dimensional, pattern of such regions on a single substrate. These regions, in particular because of their large aspect ratio, may also intersect each other, thus allowing the production of “compound-regions” or “compound-domains”, such term meaning a structure having a shape more complicated than simply “rod-like” or “cylindrical”. The regions in accordance with the present invention, and, in particular, such “compound-regions” appear to be particularly useful for photonic applications (JOANNOPOULOS, JOHN D., ROBERT D. MEADE AND JOSHUA N. WINN. Photonic Crystals. Molding the Flow of Light. Princeton University Press:. 1995, ISBN: 0-691-03744-2).

Domains arranged in the aforementioned pattern can be produced with different individual sizes and optical/dielectric properties.

Substrate materials useful for the present invention comprise all materials capable of undergoing an irreversible change in their optical and/or dielectric properties, upon undergoing a temporary increase in their temperature. Examples for substrate materials useful for the present invention are glasses, in particular certain doped and photochromic glasses, materials where the temperature increase causes optically active phase transitions such as changes in isotropy and polarization, materials where chemical reactions are initiated leading e.g. to changes in refractive index or transmission, etc. The magnitude of the changes in optical and dielectric properties may correlate with temperature allowing for a precise adjustment of the domain properties by temperature control and leading in most cases to a gradual change along the radial axis of these properties within the domain. On the other hand, the usage of materials exhibiting a certain temperature threshold for optical/dielectric property changes allows the production of domains with sharply defined boundaries. A material exhibiting a temperature threshold for dielectric and/or optical properties is a material wherein such properties change once the temperature of the material has temporarily reached such threshold, and wherein such properties do not change if the material temperature does not reach such threshold. The usage of materials having a saturation temperature at which no further property changes occur is suited for the production of domains with cores having (radially) constant optical/dielectric properties. A material exhibiting a saturation temperature for dielectric and/or optical properties is a material wherein such properties do not change further even when the temperature of the material is further increased. The usage of materials where both, the threshold and the saturation temperature are very near or identical, allows for the production of domains with (radially) constant optical/dielectric properties. As outlined previously, the local substrate temperature that is necessary for the formation of regions in accordance with the present invention, i.e. for introducing a change of dielectric and/or optical properties, can be controlled by the time course and magnitude of the electrical power provided and transformed into heat during the breakdown process.

In one embodiment, the dielectric/optical property that is preferably changed in a region in accordance with the present invention is the refractive index inside such region, as a result of which such region may be able to show total reflection of light at the interface to the remainder of the substrate outside of said region. Light coupled into such a region will be totally reflected within such region, and this region therefore may act as a waveguide. The coupling/intersection of several such regions allows the formation of photonic structures which are otherwise difficult to manufacture.

Furthermore, in some embodiments, the substrate into which regions in accordance with the present invention are to be introduced, may be attached to a conducting or semi-conducting support, such as a metal layer or silicon wafer. During the performance of the method according to the present invention, the support will be connected or exposed to one electrode of the overall dielectric breakdown device. Any changes introduced into the region will usually not extend into such support. After performance of the present method, such support may be fully or partially removed from the substrate. A conductive layer may also be added after the domain formation to e.g. provide for light reflection of the substrate surface or for coupling to other optical components.

A device for performing the method according to the present invention comprises preferably a voltage supply being capable of providing the necessary discharge current/power during domain formation, which typically requires an impedance in the range or below the ohmic resistance of the substrate towards the end of the discharge process—or a higher impedance voltage supply and an energy storage element electrically connected in parallel to said voltage supply, means to receive and hold an electrically insulating substrate in a defined place while a region having altered optical and/or dielectric properties is being formed, at least two electrodes electrically connected to said voltage supply and said energy storage element, said at least two electrodes being positioned such that, if an electrically insulating substrate is present in said defined place, said electrodes either touch said substrate or touch a medium, said medium being in contact with said substrate, wherein said medium is a liquid or a gaseous medium which is electrically conducting or can be made electrically conducting, e.g. by ionization, a current and power modulating element, said current and power modulating element being part of the electrical connection between said energy storage element and said electrodes, means to raise locally the substrate conductivity besides the applied voltage, that is to apply additional energy, preferably heat to said substrate, wherein said means is one electrode or said at least two electrodes or is an additional heat source. Preferably, said voltage supply, said energy storage element, said at least two electrodes, said medium, said current and power modulating element, and said means to apply energy are as defined above. Preferably, said means to receive and hold an electrically insulating substrate are fixing means such as a holder, a resting surface, a clamp, a pin and socket, a recess for receiving said substrate, and any combination of such fixing means including several pins, several recesses and the like. In preferred embodiments, the device according to the present invention further comprises an electrically insulating substrate, wherein, more preferably, said electrically insulating substrate is as defined above.

As used herein, the term “energy storage element” refers to a device or structure or apparatus which allows to store electrical energy in it which energy can subsequently be regained, if and where needed. In the method and device according to the invention, usually this “energy storage element” is electrically connected to the substrate in parallel such that, effectively, any electrical energy stored in said energy storage element is also stored “in” or “across” said substrate. Usually electrical energy is stored in such an energy storage element by charging said energy storage element with electrical energy obtained from a common energy source such as a commercially available voltage supply. It should be noted that an “energy storage element” according to the present invention has preferably a low impedance, typically ≦100 kΩ. Because of the low impedance of the energy storage element, the characteristics of the voltage supply used to charge the energy storage element do not play a role anymore for the subsequent process of regaining the energy from the energy storage element, and therefore the energy stored in such an energy storage element can be discharged very quickly and high current values in the order of (10 mA to 10 A). The process of discharging said electrical energy from said energy storage element is herein also referred to as “dissipating said electrical energy”. As used herein, such “dissipating” of electrical energy is effectively the transformation of electrical energy into heat. Typical examples of an energy storage element according to the present invention are a capacitor or a coil.

The amount and rate of dissipation of the electrical energy is controlled by a “current and power modulating element” which typically is a device, structure or apparatus that is in the connection between the energy storage element and the substrate, and therefore any electrical energy that is provided from said energy storage element as an electrical current flowing into and through the substrate, is controlled, e.g. attenuated in user defined manner, via such “current and power modulating element”. Consequently such “current and power modulating element” allows to control the current flow as well as the trans-substrate voltage. In the simplest case, such current and power modulating may be an ohmic resistor between said energy storage element and said substrate.

Under some circumstances the energy storage element may also be an intrinsically forming capacitance of the substrate, which may play a role if the substrate has a small thickness, e.g. <50 μm, and which forms if, due to the application of a voltage across said substrate, the gaseous medium around the substrate in the boundary layer becomes ionised. Here such capacitance may also be used as an energy storage element, in addition to an “external” energy storage element, such as a capacitor, or also as the sole energy storage element. If this intrinsic capacitance is the sole energy storage element, the rate of dissipation of said energy may be controlled by limiting the area exposed to said medium, thereby effectively limiting the amount of energy stored in said capacitance, and by influencing its conductivity by e.g. changing the pressure, composition and temperature of the medium. In the latter case, effectively the surrounding medium is used as current and power modulating element. For example, a conductive mediator, such as a liquid metal layer or an electrolyte, may be placed between the electrodes and the substrate.

As used herein, the term “to significantly heat” a substrate means a process whereby the temperature of the substrate is increased by at least 30K.

In the following reference is made to the figures which are given as examples and which show the following:

FIG. 1 shows a possible experimental Setup. The substrate S, a doped glass, was placed between two electrodes A and K, the latter being prepared as heating filament (≈1 mm², distance ≈100 μm, T≈1200 K) (1 μm=1 um). A high impedance (20 MΩ) generator charged the capacitor C (50-470 pF) providing a low impedance voltage source and inherent energy limitation (CU₀²/2≈1-450 mJ) to the process. The maximum substrate current was controlled by R. Voltage-dependent polarisation of the dielectric substrate material formed an additional ‘parasitic’ capacitance C_{S}.

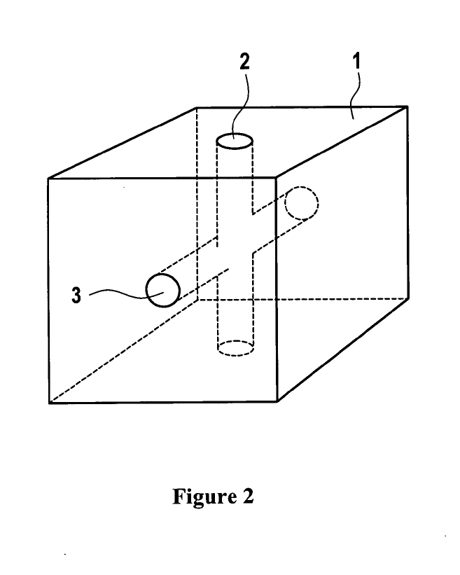

FIG. 2 shows an embodiment of a three-dimensional pattern of regions having altered dielectric and/or optical properties, in accordance with the present invention, wherein there are two regions (2, 3) having altered optical and/or dielectric properties which have been manufactured from different sides of the substrate (1) which regions intersect with each other and represent a compound region, as outlined and defined above.

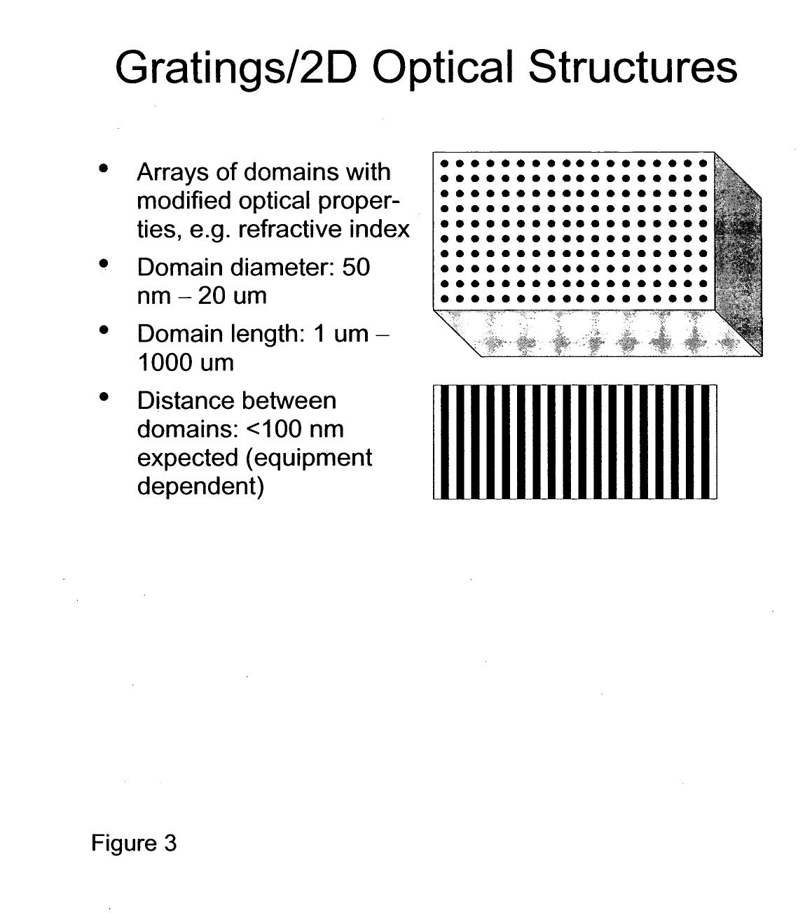

FIG. 3 shows an embodiment of a two-dimensional pattern of regions or domains created in accordance with the present invention wherein domains having modified optical properties, for example a modified refractive index in comparison to the bulk of the substrate, are arrayed within the substrate (top and side view). Preferably, the domain diameter in these embodiments is in the range of from 50 nm to 20 um, and the domain length is in the range of from 1 um to 1000 um (1 um=1×10⁻⁶ m). The distance between the individual domains can be as low as ≦100 nm, but may, of course, also be larger than this. Such distance is mainly equipment-dependent.

FIG. 4 shows an embodiment of three-dimensional pattern of regions or domains, wherein regions (“domains”) having altered optical and/or dielectric properties are introduced from different substrate sides depending on the material thickness. Such domains can intersect, and the individual spacing and the domain size in such an array are variable. The change in dielectric/optical properties, for example in the refractive index of each domain, may be controlled individually for each domain. Shown in FIG. 4 is a side view of a three-dimensional structure having an array of domains and consisting of intersecting high aspect ratio domains with modified refractive index.

FIG. 5 exemplifies the progression of the radial temperature distribution within a substrate prior to evaporation, Δt=62 ps. For very fast heating, except for very narrow T-profiles <10 nm, heat conduction has no influence on temperature distribution. Also, heat capacity rc has no significant effect on the final temperature distribution; the T-profile is under these circumstances mainly determined by E and the material parameter s(T). The width of the T-profile correlates inversely to the activation energy W. (U₀=10 kV, C=33 pF, h=150 mm, doped glass). It should be noted that, in accordance with the present invention, evaporation is to be avoided.

FIG. 6 exemplifies the control of the radial temperature profile and therefore the optical domain by properties by using a series resistance R as power modulating element under otherwise constant conditions. The radial temperature profile has been modelled at evaporation onset (3000 K) as a function of the series resistance R shown in FIG. 1 (U₀=10 kV, C=33 pF, h=150 μm, doped glass). In accordance with the present invention, however, it should be noted that evaporation should be avoided such that no material or no substantial amount of material is ejected from the substrate.

FIG. 7 depicts an embodiment for the formation of holes or structural changes using an insulating layer. The insulating layer (2) is attached to the substrate (1) and placed between two electrodes (3, 3′) connected to a user and optionally process controlled voltage source (4). Upon application of a voltage between the electrodes sufficient for dielectric break-down within the substrate the insulating layer reduces the actual voltage across the substrate below the break-down threshold. Upon further increase of the voltage or optionally heat induced local breakage of the insulating layer using either laser 5 or 5′ the energy dissipation step inside the substrate is triggered. The duration (as well as the voltage source properties) determine the extension of the region where energy was dissipated and therefore the temperature profile within this substrate region.

FIG. 8 illustrates the substrate (1)—insulating layer (2) compound undergoing modification. In (A) the combination is shown before modification, in (B) energy has been dissipated and the actual modification process has been terminated. The substrate region has been altered (6) and the insulating layer is opened (7). (C) shows the combination after the insulating layer has resealed. This last step may occur spontaneously (as with liquid insulators such as water or dodecane or with solid insulators that heat up sufficiently to reflow such as paraffin wax) or after local or global re-heating of the substrate. For the latter process a laser used for process initiation may be used (in absence of voltage) to heat the insulator surrounding the modified region.

FIG. 9 illustrates the formation of multiple structures, such as holes, in close proximity on a single substrate. After formation of holes (6) in the substrate (1) and resealing (7) of the insulating layer (2) the substrate attached to a moveable support (8) is moved, voltage applied to the electrodes (3, 3′) and the dissipation process restarted using a focused laser beam (5). Closing of the pre-existing holes is—depending on the inter-hole distance and voltage magnitude—required to prevent pre-discharges through the already existing holes where e.g. a gas such as air breaks down much quicker than the actual substrate (e.g. glass).

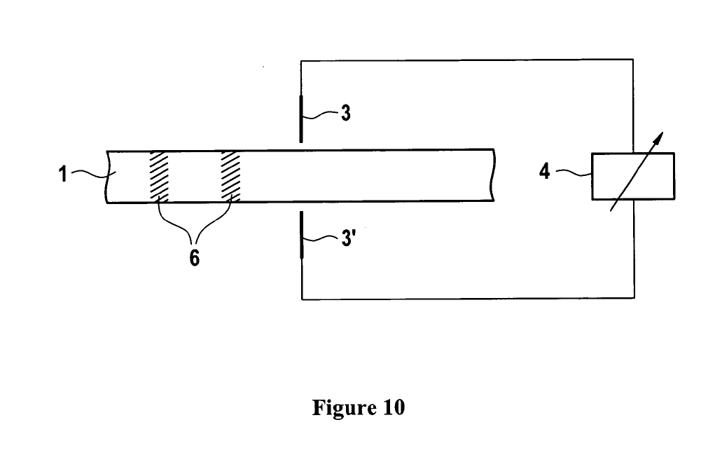

FIG. 10 depicts and embodiment for the introduction of structural changes using voltage induced dielectric break-down rather than laser induction. For that electrodes (3, 3′) are placed in close proximity to the substrate (1) determining the break-down and energy release position on the wafer. The close substrate-electrode distance also allows for relatively low voltages to start the dissipation process, in particular in semiconductors for which this setup is most suited. The voltage source (4) is programmed to either produce open holes or microstructural changes such as a transformation of a crystalline region into an amorphous region (6). Voltage magnitude and application time determine the extension and the degree of transformation inside the substrate. High voltages for short durations provide regions narrow in diameter while longer application time, and if necessary lower voltages to avoid evaporation, provide larger diameter regions. The newly formed regions (6) may have a higher electrical resistivity than the untransformed substrate thus avoiding short-circuiting and the usage of insulating layers.

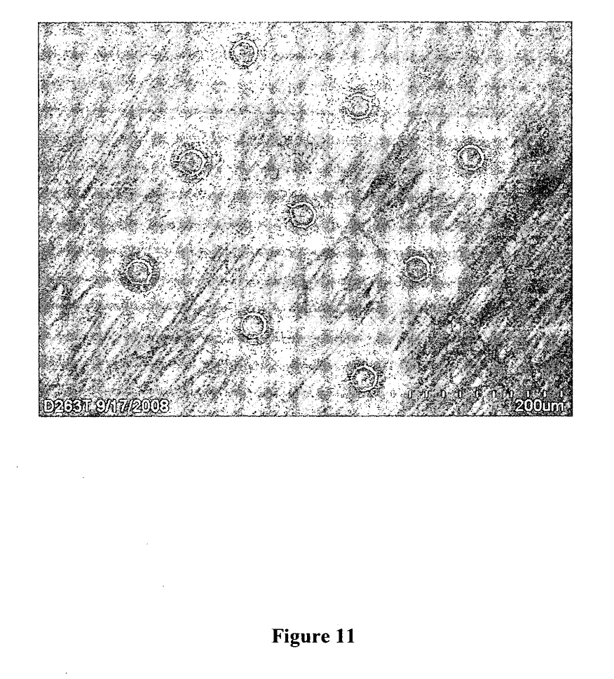

FIG. 11 shows an array of holes generated in a 150 um thick borosilicate glass substrate using an insulating layer of paraffin wax of a thickness <500 um on one side. The DC voltage applied was 9 kV and was switched off at a trans-substrate current of 300 uA. The discharge process was initiated by laser irradiation at a wavelength of 10.6 um (CO2-laser) and a power of 5 W for 20 ms using a focal spot of 100 um in diameter. Other insulating layers (see above) are also possible (results not shown).

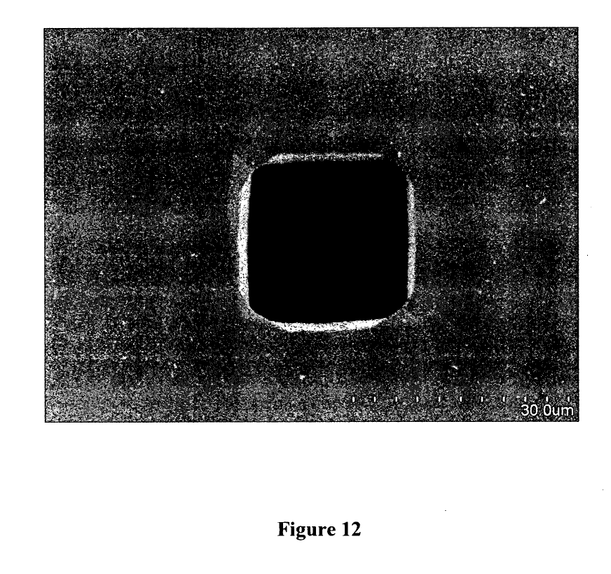

FIG. 12 shows a through-hole generated in a silicon substrate using the method employing a final etching step after introducing a structural change without creating a through-hole, as outlined above. The silicon wafer was 254 um thick with an electrical resistivity of >100 Ωcm (P-Boron doped). A DC voltage of 2 kV was applied for 20 ms without using an insulating layer and additional heat. The distance between electrode and substrate was approximately 0.4 mm on each side. KOH (50%, 80° C.) was used as the etching agent, and the square-like appearance of the hole results from the <100> orientation of the wafer.

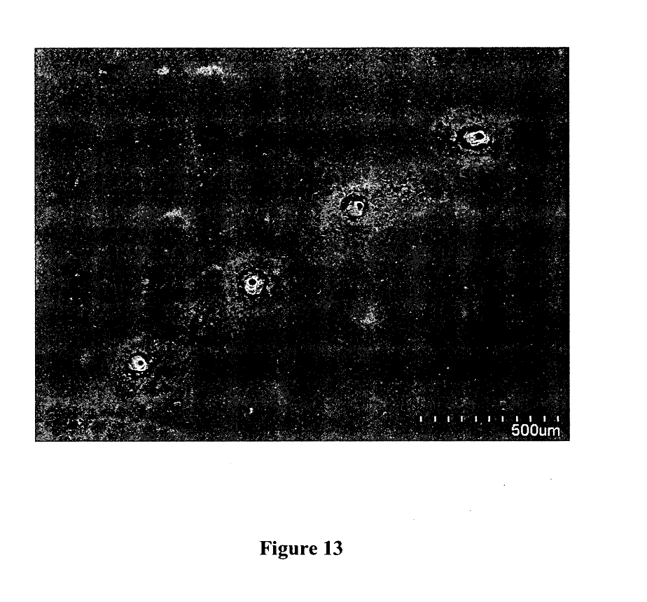

FIG. 13 shows an array of holes generated in a silicon substrate using a <1 mm thick insulating layer of hot melt adhesive (Pattex PTK6) on one side. The silicon wafer had a thickness of 275 um, an electrical resistivity of >300 Ωcm (P-Boron doped) and <100> orientation. The DC voltage applied was 7 kV for 600 ms. Electrode distance was approximately 0.4 mm to the substrate and 1 mm to the insulating layer. The discharge process was initiated by laser irradiation at a wavelength of 10.6 um (CO2-laser) and a power of 3.5 W for 600 ms using a focal spot of 100 um in diameter. Other insulating layers, such as dodecane, etc. (see above) are also possible (results not shown).

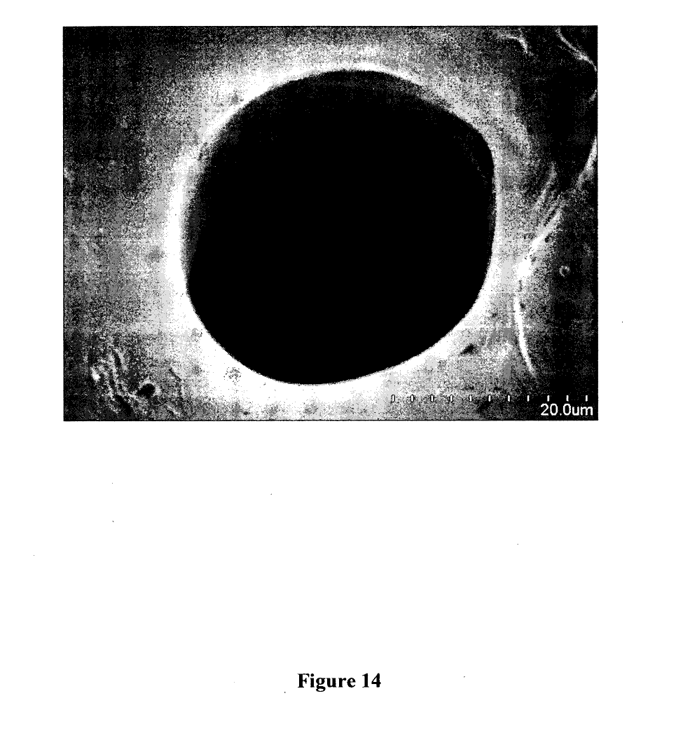

FIG. 14 shows an enlarged picture of a hole generated in a 254 um thick silicon wafer with an electrical resistivity of >100 Ωcm (P-Boron doped) and <100> orientation. The hole was created by applying a DC voltage of 3 kV for 400 ms, without using an insulating layer and additional heat. The distance between electrode and substrate was approximately 0.5 mm on each side. The substrate has been subsequently polished.

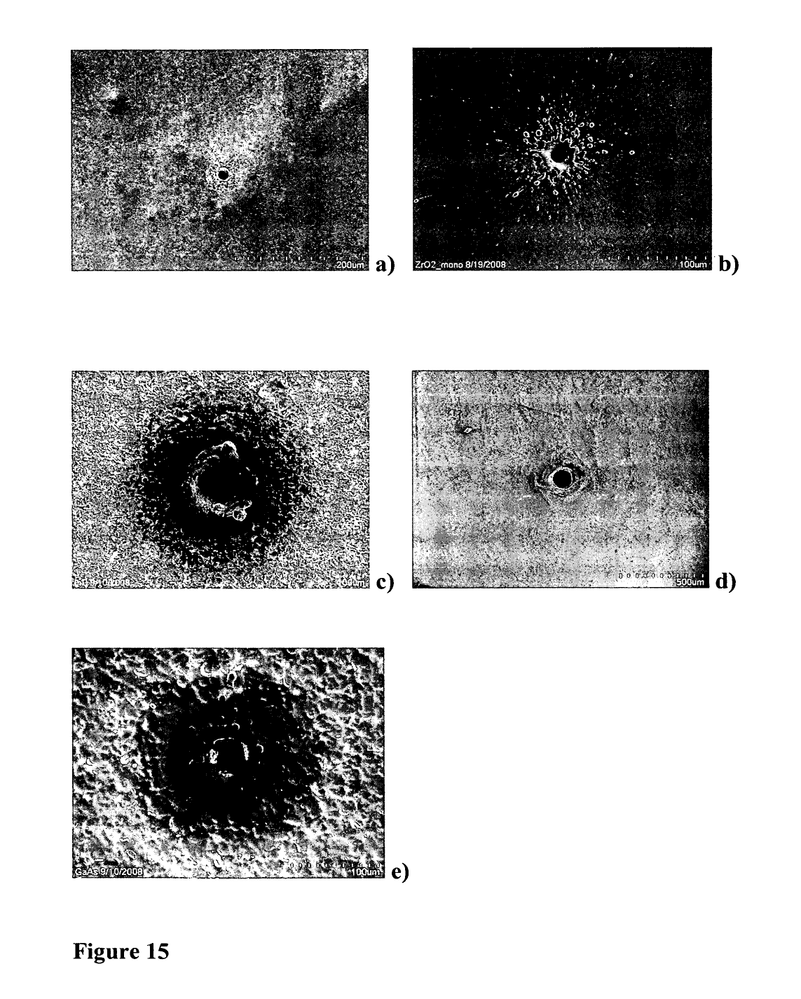

FIG. 15a) shows a hole generated in a 400 um thick substrate of monocrystalline zirconia (ZrO2) using a voltage of 10 kV for 800 ms and an irradiation of laser light at a wavelength of 10.6 um (CO2-laser), power of 10 W, focal diameter of 100 um for initiation.

FIG. 15b) shows a hole generated in a 300 um thick substrate of polycrystalline zirconia (ZrO2) using a voltage of 8 kV for 500 ms and an irradiation of laser light at a wavelength of 10.6 um (CO2-laser), power of 8 W, focal diameter 100 um for initiation. After hole formation the surface was mechanically polished.

FIG. 15c) shows a hole generated in a 400 um thick substrate of sapphire using a voltage of 10 kV for 2000 ms and an irradiation of laser light at a wavelength of 10.6 um (CO2-laser), power of 22 W, focal diameter 100 um for initiation.

FIG. 15d) shows a hole generated in a 500 um thick substrate of indium phosphide with an electrical resistivity of 0.0016 Ohm cm and orientation <100> using an insulating layer of Parafilm M. The applied voltage was 11 kV for 200 ms. The process was initiated by irradiation of laser light at a wavelength of 1064 nm (fiber-laser), power of 20 W, focal diameter of approximately 20 um.

FIG. 15e) shows a hole generated in a 400 um thick substrate of gallium arsenide with an electrical resistivity of 0.158 Ohm cm and orientation <111> using an insulating layer of Parafilm M. The applied voltage was 10 kV for 200 ms. The process was initiated by irradiation of laser light at a wavelength of 1064 nm (fiber-laser), power of 20 W, focal diameter of approximately 20 um.

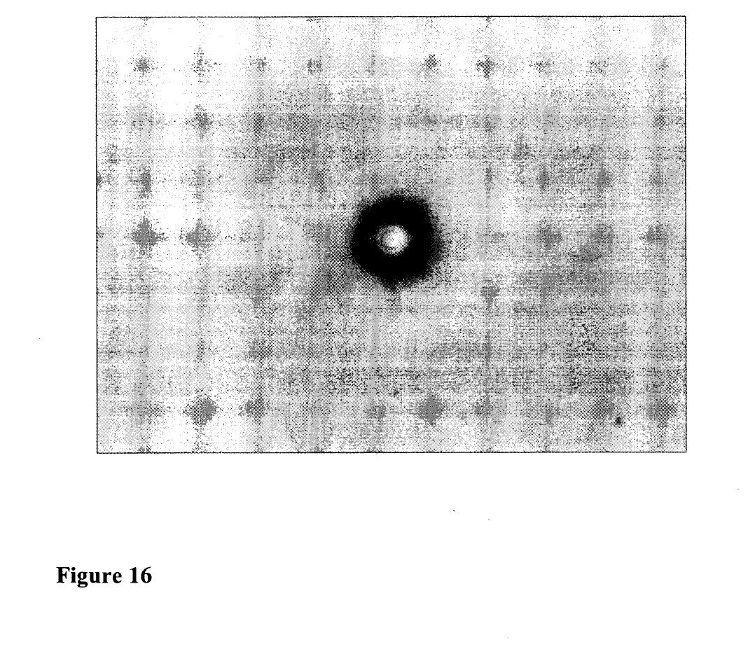

FIG. 16 shows an image of an area of changed optical properties in a 150 um thick borosilicate glass substrate. The optical structure was produced by applying an AC voltage with a duty cycle of 20% and a frequency of 45 kHz for a time of 70 ms. The picture was obtained using a transmission optical microscope with a magnification of 40×.

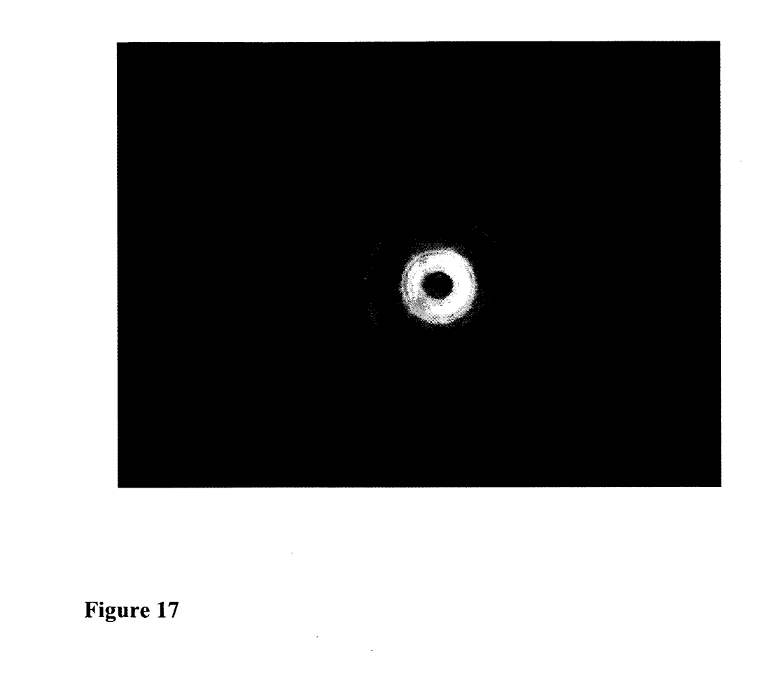

FIG. 17 shows an image of an area of changed optical properties in a 150 um thick borosilicate glass substrate. The optical structure was produced by applying a DC voltage of 8 kV and a series resistance of 4.7 kOhm. The discharge was initiated by laser irradiation at a wavelength of 10.6 um with power 3 W. The picture was obtained using a transmission optical microscope with a magnification of 40× and a phase contrast filter.

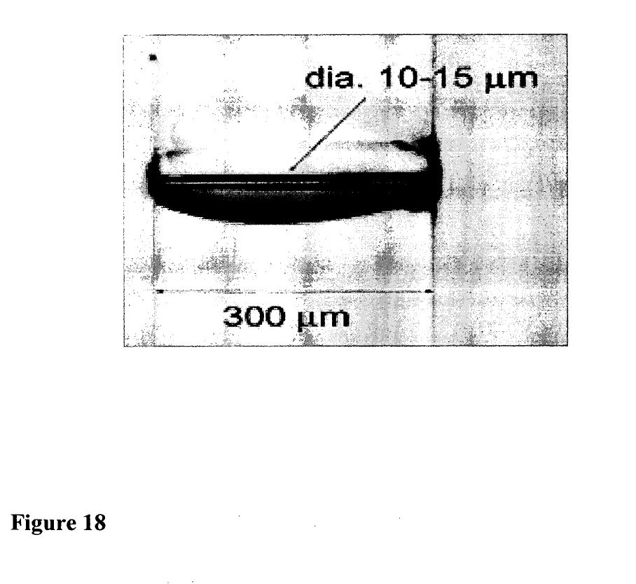

FIG. 18 shows a cut through image of a region with changed optical properties around a through hole in a 300 um thick borosilicate glass substrate. The picture was obtained using a confocal microscope.

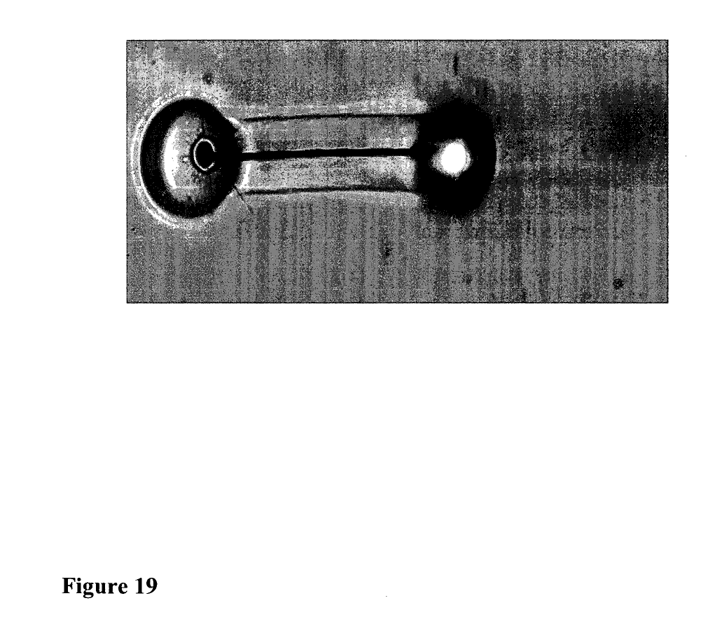

FIG. 19 shows an image of a cylindrical region with changed optical properties in a 700 um thick borosilicate glass substrate produced by a DC voltage of 8 kV and a capacitor of 1 nF. Discharge was initiated by laser irradiation at a wavelength of 10.6 um with power of 5 W. The picture was obtained using a transmission optical microscope and a slightly tilted sample so as to obtain a side view on the cylindrical region through the substrate.

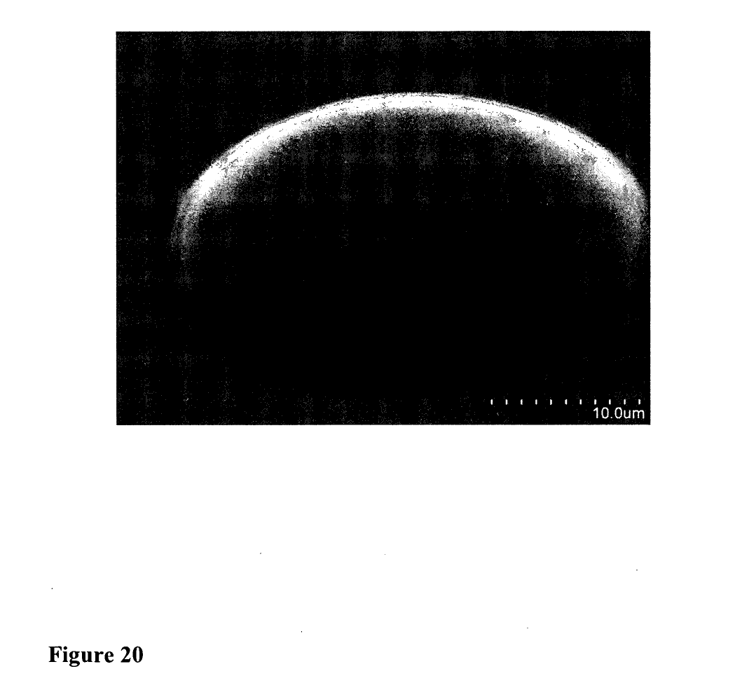

FIG. 20 shows an image of a microlense created on the surface of a 150 um thick borosilicate glass sample (tilted 40°). The lense was obtained by applying a DC voltage of 6 kV and the discharge was initiated by laser irradiation at a wavelength of 10.6 um with power 3 W.

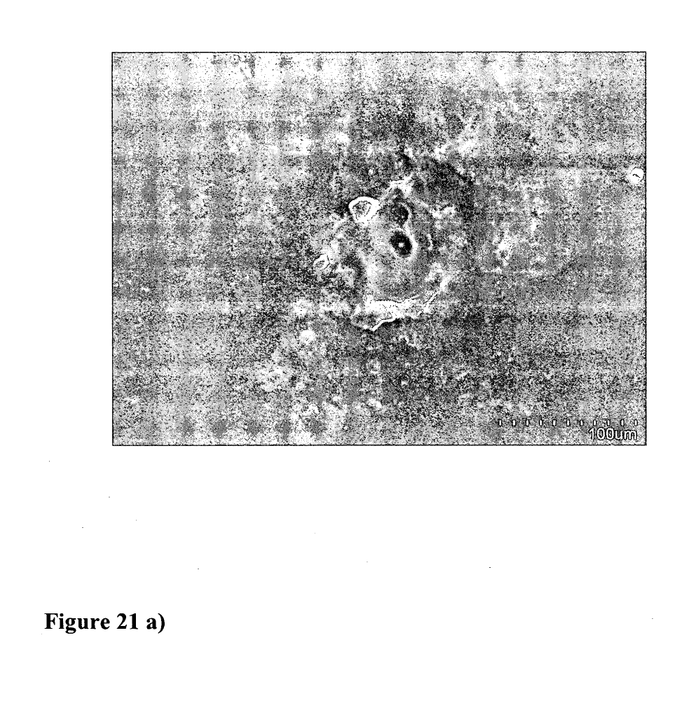

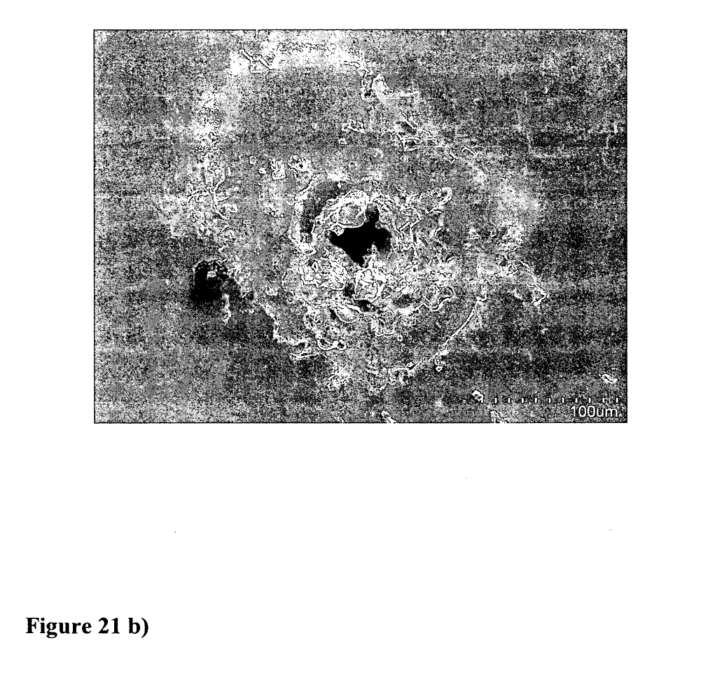

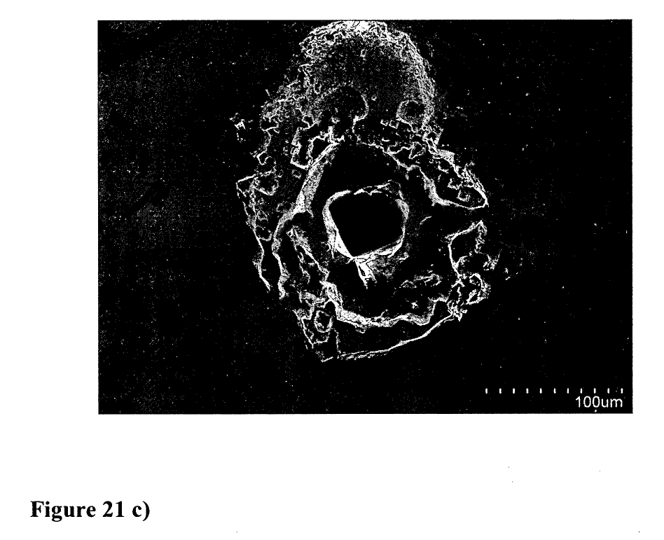

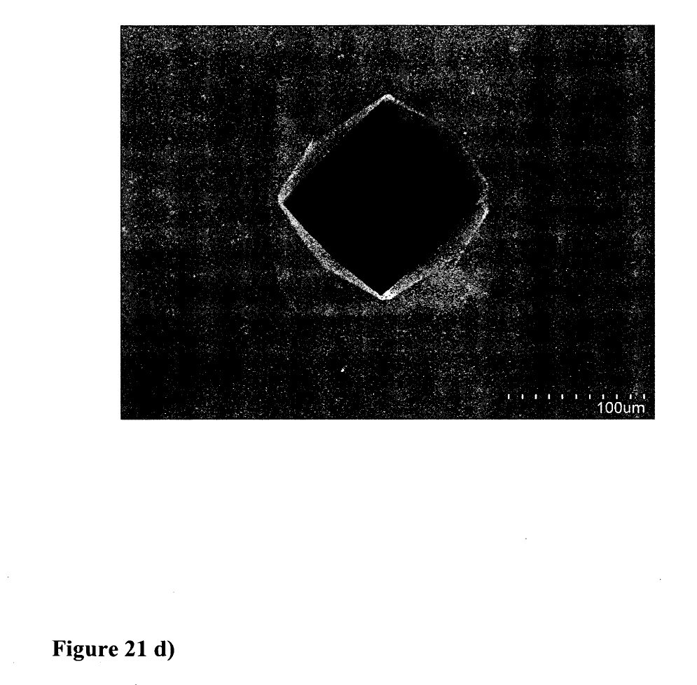

FIG. 21 a) shows an image of a silicon substrate (surface not polished) with electrical resistivity >100 Ohm cm, thickness 200 um, orientation <100>, where the infrared-optical properties were locally changed within a cylindrical region through the substrate. The structure was introduced by applying a DC voltage of 2 kV for 40 ms which led to an irreversible transformation from crystalline (lower refractive index) to amorphous (higher refractive index) state within the heated region.

The change in optical properties is indirectly proven by subsequent etching steps since amorphous silicon shows a significantly higher etching rate compared to crystalline silicon. For etching 30% KOH solution was used for 20 min (FIG. 21b), 40 min (FIG. 21c) and 60 min (FIG. 21d).

The features of the present invention disclosed in the specification, the claims and/or in the accompanying drawings, may, both separately, and in any combination thereof, be material for realizing the invention in various forms thereof.

1. A method of introducing a change of dielectric or optical properties or both in a first region of an electrically insulating or electrically semiconducting substrate, such that, after performance of said method, said first region has altered dielectric and/or optical properties in comparison to other regions surrounding said first region, said method comprising the steps:
a) providing an electrically insulating or electrically semiconducting substrate, which has optical or dielectric properties that may be irreversibly altered upon a temporary increase in substrate temperature, and which, optionally, has an electrically conducting or semi-conducting or insulating layer of material attached,
b) providing electrical energy to said substrate using a voltage supply, said electrical energy being sufficient to significantly heat and/or melt parts or all of said first region, said electrical energy not being sufficient to cause a significant ejection of material from said first region,
c) optionally, applying additional energy, preferably heat, to said substrate, preferably to a part of said substrate comprising said first region, and thereby initiate a current flow and, subsequently, a dissipation of said electrical energy within said substrate to define the location of said first region in which said change of dielectric and/or optical properties is to be introduced on said substrate, and
d) dissipating said electrical energy, wherein said dissipating manifests itself in a current flow within said substrate and wherein the rate of dissipating said electrical energy is controlled by a current and power modulating element, said current and power modulating element being either part of an electrical connection between said voltage supply and said substrate, or being part of said voltage supply, said dissipating introducing said altered dielectric and/or optical properties in said first region of said substrate.

2. The method according to claim 1, wherein said electrical energy is not sufficient to cause the formation of a through hole or through channel in said first region.

3. The method according to claim 1, wherein said first region, after performance of said method, has altered optical properties in comparison to other regions surrounding said first region.

4. The method according to claim 3, wherein said optical properties are selected from transmission, reflection, refraction, dispersion, filtering, polarization, dielectric constant, magnetic permeability, optical isotropy, optical anisotropy of light interacting with said first region, and any combination of the foregoing properties.

5. The method according to claim 1, wherein step b) is performed by applying a voltage across said first region of said substrate by means of said voltage supply, said voltage supply being electrically connected to said substrate

6. The method according to claim 5, wherein step d) occurs in that said voltage supply supplies an electrical current to said substrate and, preferably, to said first region, and said electrical current and/or the time over which said current is supplied is controlled by said current and power modulating element or, if said current and power modulating element is part of said voltage supply, by said voltage supply, said voltage supply having a variable impedance, said variable impedance being adjusted under the control of an automated control and/or feedback circuit.

7. The method according to claim 6, wherein said current and power modulating element is an electronic feedback mechanism which, preferably, comprises a current and/or voltage analysis circuit such as a trigger circuit alone or as part of a user programmed device, such as a computer, said current and/or voltage analysis circuit preferably being capable of controlling the trans-substrate voltage and electrical current flow of step d) according to user-predefined procedures, such as steadily reducing or turning off such voltage supply and/or energy storage element output once a user specified trans-substrate current threshold is exceeded.

8. The method according to claim 7, wherein said electronic feedback mechanism is an ohmic resistor which is connected in series between said substrate and said voltage supply.

9. The method according to claim 8, wherein said ohmic resistor is chosen such that it has a resistance in the range of from 0.01-100 kΩ if said substrate has a thickness ≧1 μm, and a resistance >100 kΩ if said substrate has a thickness <1 μm.

10. The method according to claim 8, wherein said ohmic resistor is chosen in terms of its resistance such that said resistor leads to a reduction of the trans-substrate voltage of at least a factor of 2, preferably a factor of 5 during step d), compared with otherwise identical conditions but in the absence of a resistor.

11. The method according to claim 5, wherein step b) is performed by applying a voltage across said first region of said substrate by means of said voltage supply and charging an energy storage element with said electrical energy, said energy storage element being electrically connected in parallel to said substrate and said voltage supply, and wherein said current and power modulating element is part of the electrical connection between said energy storage element and said substrate.

12. The method according to claim 11, wherein the amount of said electrical energy stored across said substrate and charged to said energy storage element is user-defined in relation to substrate parameters, such as substrate area, substrate thickness, heat capacity of substrate, coefficient of thermal conduction of substrate, and process parameters, such as maximum temperature occurring during step d).

13. The method according to claim 12, wherein said amount of electrical energy is in the range of from 1-5000 mJ/mm substrate thickness, preferably 10-500 mJ/mm substrate thickness.

14. The method according to claim 1, comprising the step:
c) applying additional energy, preferably heat, to said substrate, preferably to a part of said substrate comprising said first region, and thereby initiate a current flow and, subsequently a dissipation of said electrical energy within said substrate.

15. The method according to claim 14, wherein by the performance of step c), the position of said first region in which a change of dielectric and/or optical properties is introduced, is defined.

16. The method according to claim 1, wherein said first region, after performance of said method, has cross sectional dimensions in the range of from x to y, wherein x>1 nm and y<50 μm.

17. The method according to claim 1, wherein said first region extends from a first surface of said substrate to the inside of said substrate and, preferably, to a second surface of said substrate which second surface is opposite said first surface.

18. The method according to claim 1 wherein said first region has a shape determined by a path of energy dissipation of step d) and extends across said substrate.

19. The method according to claim 1, wherein said first region has a rod-like shape or cylindrical shape or paralleliped shape.

20. The method according to claim 18, wherein said first region has uniform optical properties along said path of energy dissipation as defined in claim 18.

21. The method according to claim 17, wherein said first region extends perpendicular from said first surface to said second surface.

22. The method according to claim 1, wherein said optical properties are refraction of light interacting with or incident upon said first region and a corresponding refractive index of material within said first region.

23. The method according to claim 22, wherein said first region has a light refraction and corresponding refractive index such that light coupled into said first region is totally reflected within said first region.

24. The method according to claim 1, wherein said first region has an aspect ratio of ≧10, preferably ≧100.

25. The method according to claim 1, wherein said substrate provided in step a) has an electrically conducting or semi-conducting or insulating layer of material attached, e.g. a metal layer or a silicon layer.

26. The method according to claim 25, wherein said method comprises the further step e) fully or partially removing said electrically conducting or semi-conducting or insulating layer of material from said substrate.

27. The method according to claim 1, wherein performing steps a)-d) does not lead to a change of geometry or physical dimensions of said substrate.

28. The method according to claim 27, wherein performing steps a)-d) does not lead to a change of volume or weight of said substrate.

29. The method according to claim 1, wherein said method including steps a)-d) is additionally performed in a second region and optionally further regions of said substrate, wherein said performance of said method is done concomitantly with the method performed in said first region, using multiple electrodes and using an optical pattern of light spots generated on a surface of said substrate, e.g. generated by a laser source, wherein each light spot determines the locations of said second region and further regions of said substrate in which said altered dielectric and/or optical properties are to be introduced.

30. The method according to claim 29, wherein said first, second and further regions are alike in shape and dimensions.

31. The method according to claim 29, wherein said first, second and further regions are located parallel to each other.

32. The method according to claim 29, wherein at least some of said first, second and further regions intersect with each other.

33. The method according to claim 29, wherein at least some of said first, second and further regions having altered dielectric and/or optical properties are generated from a first surface of said substrate and others of said first, second and further regions having altered dielectric and/or optical properties are generated from a second surface of said substrate, said second surface of said substrate being opposite said first surface, wherein, preferably, said second surface is inclined or parallel or perpendicular to said first surface.

34. The method according to claim 11, wherein said energy storage element and, preferably also said voltage supply, is connected to said substrate by electrodes, which electrodes either touch said substrate or touch a medium, said medium being in contact with said substrate, wherein said medium is a liquid or gaseous or solid medium which is electrically conducting or can be made electrically conducting, e.g. by ionisation.

35. The method according to claim 34, wherein said energy storage element and said voltage supply are connected to said substrate by the same electrodes.

36. The method according to claim 11, wherein said voltage supply is a high impedance voltage supply, wherein preferably said high impedance voltage supply has an impedance >10 kΩ, more preferably >100 kΩ and, even more preferably >1 MΩ.

37. The method according to claim 11, wherein said energy storage element is a low impedance energy storage element, wherein preferably said low impedance is an impedance ≦10 kΩ.

38. The method according to claim 11, wherein, upon dissipation of said electrical energy, said voltage supply provides further electrical energy to be stored across the substrate by charging it to said energy storage element.

39. The method according to claim 38, wherein steps b)-d) are repeated at least once, preferably several times, with a user-defined delay after the end of step d) and before performance of a next step b).

40. The method according to claim 11, wherein said dissipation of said electrical energy in step d) occurs by an electrical current being supplied from said energy storage element to said substrate and through said first region and thereby transforming said electrical energy into heat which heat will heat and/or melt substrate material in said first region.

41. The method according to claim 40, wherein said electrical current is supplied to said substrate via said current and power modulating element, said current and power modulating element controlling and/or modulating step d), and thereby controlling the transformation of said electrical energy into heat.

42. The method according to claim 41, wherein said electrical current being supplied to said substrate and subsequently flowing through said substrate in step d) has a temporary maximum of 1 uA-1 A, if maintenance of the physical dimensions or volume or weight of said substrate is required.

43. The method according to claim 40, wherein said dissipation in step d) occurs at a stored electrical energy resulting in a trans-substrate voltage across said substrate of at least 5V/micrometer substrate thickness.

44. The method according to claim 41, wherein said current and power modulating element is an electronic feedback mechanism which, preferably, comprises a current and/or voltage analysis circuit such as a trigger circuit alone or as part of a user programmed device, such as a computer, said current and/or voltage analysis circuit preferably being capable of controlling the trans-substrate voltage and electrical current flow of step d) according to user predefined procedures, such as steadily reducing or turning off such voltage supply and/or energy storage element output once a user specified trans-substrate current threshold is exceeded.

45. The method according to claim 1, wherein said additional energy, preferably heat, originates either from an additional energy source, preferably a heat source, or from performing step b) on said substrate.

46. The method according to claim 45, wherein said additional energy source is a heated electrode or a heating element placed near by said substrate or a laser or other focussed light source or a gas flame.

47. The method according to claim 44, wherein said current and/or voltage analysis circuit also is capable of controlling said additional energy or heat source, if present.

48. The method according to claim 44, wherein said electronic feedback mechanism is an ohmic resistor which is connected in series between said substrate and said energy storage element.

49. The method according to claim 48, wherein said ohmic resistor is chosen such that it has a resistance in the range of from 0.01-100 kΩ if said substrate has a thickness ≧1 μm, and a resistance >100 kΩ if said substrate has a thickness <1 μm.

50. The method according to claim 48, wherein said ohmic resistor is chosen in terms of its resistance such that said resistor leads to a reduction of the trans-substrate voltage of at least a factor of 2, preferably a factor of 5 during step d), compared with otherwise identical conditions but in the absence of a resistor.

51. The method according to claim 48, wherein said ohmic resistor is tunable.

52. The method according to claim 48, wherein said ohmic resistor has a fixed resistance.

53. The method according to claim 11, wherein said energy storage element and, preferably also said voltage supply, is connected to said substrate by said electrodes via connections, which, with the exception of said ohmic resistor, if present, have a low impedance which low impedance connections are chosen such in terms of their total impedance value that they do not lead to any significant reduction of the trans-substrate voltage during step d), wherein, preferably said low impedance connections have a total impedance value ≦0.01 kΩ.

54. The method according to claim 1, wherein said current and power modulating element causes an end of step d) within a user-predefined period after onset of step d), said onset preferably being an increase in electrical current, by a factor of 2, preferably by at least one order of magnitude, or a current value >10 μA, preferably >1 mA.

55. The method according to claim 11, wherein said energy storage element being electrically connected in parallel to said substrate and said voltage supply is a capacitor or a coil.

56. The method according to claim 55, wherein said energy storage element is a capacitor.

57. The method according to claim 56, wherein said capacitor has a capacity in the range of at least 5 pF/mm substrate thickness.

58. The method according to claim 57, wherein said capacitor is connected to said substrate via said current and power modulating element, preferably via said ohmic resistor, such that said electrical energy stored using said capacitor, is dissipated via said current and power modulating element, preferably via said ohmic resistor.

59. The method according to claim 34, wherein said energy storage element is an intrinsic or intrinsically forming capacitance of said substrate which is the sole energy storage element present or is present in addition to a capacitor as defined in any of claims 56-58.

60. The method according to claim 59, wherein, if said intrinsic or intrinsically forming capacitance of said substrate is the sole energy storage element present, no electrodes connecting said energy storage element to said substrate are present, and step d) is controlled by appropriate selection of the area of said substrate which area is exposed to the surrounding medium, and/or by appropriate selection of the conductive properties of said medium being in contact with said substrate, said medium being responsible for charge carrier transport during said dissipation in step d), said conductive properties of said medium being defined by pressure, temperature, and composition of said medium, said medium thereby functioning as current and power modulating element.

61. The method according to claim 34, wherein step b) occurs by the placement of said electrodes at or near said region, preferably by placing one electrode on one side of said substrate and by placing another electrode on another side of said substrate, and by application of said voltage across said electrodes.

62. The method according to claim 1, wherein said applied voltage is purely DC.

63. The method according to claim 1, wherein said applied voltage is purely AC.

64. The method according to claim 1, wherein said applied voltage is a superposition of AC and DC voltages.

65. The method according to claim 63, wherein the frequency of said applied AC voltage is in the range of from 10² to 10¹² Hz, preferably in the range of from 5×10² to 10⁸ Hz, more preferably 1×10³ to 1×10⁷ Hz.

66. The method according to claim 63, wherein said AC voltage is applied intermittently, preferably in pulse trains of a duration in the range of from 1 ms to 1000 ms, preferably 10 ms to 500 ms, with a pause in between of a duration of at least 1 ms, preferably of at least 10 ms.)

67. The method according to claim 63, wherein said applied AC voltage is used for performing step c).

68. The method according to claim 63, wherein said applied AC voltage has parameters e.g. amplitude, frequency, duty cycle which are sufficient to establish an electric arc between a surface of said substrate and said electrodes, wherein, preferably, said electric arc is used for performing step c).

69. The method according to claim 63, wherein said applied AC voltage leads to dielectric losses in said region of said substrate, said dielectric losses being sufficient to increase the temperature of said region.

70. The method according to claim 63, wherein the frequency of said applied AC voltage is increased to reduce deviations of the current path from a direct straight line between the electrodes.

71. The method according to claim 63, wherein the frequency of said applied AC voltage is increased to minimize the possible distance between neighbouring regions, e.g. first, second and further regions.

72. The method according to claim 1, wherein in step c), heat is applied to said first region of said substrate using a heated electrode or a heating element placed near by the electrode.

73. The method according to claim 72, wherein said heated electrode is an electric heating filament and is also used to apply said voltage to said first region in step b).

74. The method according to claim 1, wherein, in step c), heat is applied to said first region of said substrate additionally or only by using an external heat source, such as a laser or other focussed light source.

75. The method according to claim 1, wherein, in step c), heat is applied to said first region of said substrate by applying an AC voltage to said first region.

76. The method according to claim 75, wherein said AC voltage is applied to said first region by said electrodes placed on opposite sides of said substrate, preferably at least one electrode being placed on one side of said substrate and at least one electrode being placed on another side of said substrate.

77. The method according to claim 76, wherein said electrodes placed on opposite sides of said substrate are also used for performing step b).

78. The method according to claim 77, wherein said AC voltage is in the range of 10³ V-10⁶ V, preferably 2×10³V-10⁵ V, and has a frequency in the range of from 10² Hz to 10¹² Hz, preferably in the range of from 5×10² to 10⁸ Hz, more preferably 1×10³ to 1×10⁷ Hz.

79. The method according to claim 1, wherein said first region, and, optionally, said second region and said further regions, is (are) a rod-like structures having a diameter in the range of from 0.01 μm to 200 μm, preferably 0.05 μm to 20 μm.

80. The method according to claim 1, wherein said electrically insulating or electrically semiconducting substrate is made of a material having a temperature threshold for changes of dielectric and/or optical properties to be introduced, below which no changes in dielectric and/or optical properties can be introduced.

81. The method according to claim 1, wherein said electrically insulating or electrically semiconducting substrate is made of a material having a saturation temperature above which no further changes in dielectric and/or optical properties can be introduced.

82. The method according to claim 1, wherein said electrically insulating or electrically semiconducting substrate is selected from a group comprising carbon-based polymers, such as polypropylene, fluoropolymers, such as Teflon, silicon-based substrates, such as glass, quartz, silicon nitride, silicon oxide, silicon based polymers such as Sylgard, aluminium based crystalline materials such as alumina, spinel, sapphire, as well as ceramics such as zirconia, semiconducting materials such as those semiconducting materials selected from elemental silicon, including doped silicon and crystalline silicon, germanium, compound semiconductors such as gallium arsenide, and indium phosphide.

83. The method according to claim 1, wherein said substrate is provided in step a) within a medium (solid, liquid or gas) that reacts with a surface of said substrate during steps b), c) and/or d).

84. A substrate produced by the method according to claim 1.

85. The substrate according to claim 84, having at least a first region having altered dielectric and/or optical properties in comparison to other regions where no step d) has taken place, or having an array of regions having altered dielectric and/or optical properties in comparison to other regions where no step d) has taken place.
